(19) United States
(12) Patent Application Publication
(10) Pub. No.: US 2025/0132177 A1
(43) Pub. Date: Apr. 24, 2025

(54) Apparatus and Method for Precision Component Positioning

(71) Applicant: Sangtera, Inc., Lexington, MA (US)

(72) Inventor: Tairan Wang, Lexington, MA (US)

(21) Appl. No.: 18/922,744

(22) Filed: Oct. 22, 2024

Related U.S. Application Data
(60) Provisional application No. 63/592,424, filed on Oct. 23, 2023.
(60) Provisional application No. 63/609,043, filed on Dec. 12, 2023.
(60) Provisional application No. 63/624,886, filed on Jan. 25, 2024.
(60) Provisional application No. 63/676,581, filed on Jul. 29, 2024.

(51) Int. Cl. H01L 21/67; G05B 19/4099

(52) U.S. Cl. CPC H01L 21/67144; G05B 19/4099

(57) ABSTRACT

An actuator, for precision positioning of a component, includes a base layer having a surface defining a z-axis normal to the surface; a set of electro-fluidic transport substrates, disposed on the base layer, and a control port, coupled to the array of electrodes in each of the electro-fluidic transport substrates, configured to cause motion of a carrier layer therein.

### CROSS-REFERENCE TO RELATED APPLICATIONS

The present application claims priority to U.S. Provisional Application No. 63/592,424, filed on Oct. 23, 2023, U.S. Provisional Application No. 63/609,043, filed Dec. 12, 2023, U.S. Provisional Application No. 63/624,886, filed Jan. 25, 2024, and U.S. Provisional Application No. 63/676,581, filed Jul. 29, 2024, the disclosure of each which is hereby incorporated herein by reference in its entirety.

### TECHNICAL FIELD

The present invention relates to an apparatus and method for precision positioning of a component, which may, for example, be electronic, optical, or mechanical in nature. In one embodiment, the invention may be used for positioning of a semiconductor die on a semiconductor substrate.

### BACKGROUND ART

Semiconductor die-bonders typically utilize electromagnetic motors and piezo-electric actuators to place semiconductor dies on the substrate.

As demand for placement accuracy increases, more time is required to perform the positioning.

Existing models sometimes employ dual heads to perform the task, one on each side, achieving a rate of placement of up to 2000 units per hour.

The bulk of the motors and actuators typically prevents deploying more than two heads from working concurrently.

On the other hand, wafer-to-wafer bonding processes utilize significant parallelism to improve throughput, even though the bonding process itself requires more time than required for placement of a chip on a substrate. A disadvantage of parallel processing of wafer-to-wafer bonding is that it sacrifices simplicity and flexibility, by requiring the bonded components and the substrate to have matching geometry, and device yield is reduced exponentially as more wafers are bonded to create a multi-layer stack. An alternative is to place components to be bonded into a reconstituted wafer. Yet the challenge of precision placement of many components with high throughput is only transferred to the building of the reconstituted wafer, and not resolved.

### SUMMARY OF THE EMBODIMENTS

In accordance with one embodiment of the invention, there is provided an actuator stage, for precision positioning of a component. The actuator stage of this embodiment includes:
a base layer having a surface defining a z-axis normal to the surface;
a set of electro-fluidic transport substrates, disposed on the base layer, each of the substrates having:
   a set of arrays of electrodes at a spatial frequency;
   a dielectric layer, disposed over the set of arrays of electrodes and having a hydrophobic surface;
   a fluidic layer disposed over the hydrophobic surface and including a first non-conductive liquid and a second conductive liquid, wherein the first and second liquids are immiscible; and
   a carrier layer having defined hydrophilic and hydrophobic regions in selected contact with the second conductive liquid and the first non-conductive liquid, respectively, configured in a manner so that appropriate powering of the electrodes effectuates translation (i.e., motion) of the carrier layer;
   wherein any electro-fluidic transport substrate after a first one of the set is disposed over another one of the set; and
a control port, coupled to the set of arrays of electrodes in each of the electro-fluidic transport substrates, configured to cause selective delivery, to a set of electrodes in the set of arrays of electrodes, of a current pulse having a profile controlled over time to regulate an amount of charge delivered to each electrode in the set of arrays of electrodes, so as to effectuate translation of the carrier layer in the electro-fluidic transport substrate in desired fractions of the spatial frequency of the set of arrays of electrodes.

In a further related embodiment, the actuator stage has first and second subsets of electro-fluidic transport substrates, wherein:
a. each array of the set of arrays of electrodes in each transport substrate of the first subset is a linear array, and the set of arrays of electrodes are configured by the control port to cause translation of its corresponding carrier layer in x- and y-directions of an orthogonal axis system that defines a plane normal to the z-axis; and
b. each array of the set of arrays of electrodes in each transport substrate of the second subset is a circular array configured by the control port to cause rotation about the z-axis of its corresponding carrier layer.

In a still further related embodiment, the set of electro-fluidic transport substrates has a last member spaced farthest, of all members of the set, from the surface of the base layer, and the embodiment further includes a handling head, mounted over the last member of the set of electro-fluidic transport substrates, configured to removably hold onto a workpiece to be placed onto a destination structure. In another related embodiment there is provided a set of actuator stages, with each actuator stage configured in a manner as described, wherein the actuator stages of the set are configured to process a plurality of workpieces simultaneously.

In a further embodiment, the workpiece is a semiconductor die and the destination structure is a semiconductor substrate.

### BRIEF DESCRIPTION OF THE DRAWINGS

The foregoing features of embodiments will be more readily understood by reference to the following detailed description, taken with reference to the accompanying drawings, in which:

FIG. 1A is a vertical section view of the head 101 of an actuator stage in accordance with an embodiment of the present invention.

FIG. 1B is a perspective rendering of some of the actuator stage components of FIG. 1A.

FIG. 1C is an exploded view of the layers shown in FIG. 1B.

FIG. 2A is a vertical section of one embodiment of a functional cell of an electro-fluidic transport substrate 201 in accordance with an embodiment of the present invention.

FIG. 2B is an enlarged view of the right end corner of the droplet 204 of FIG. 2A.

FIG. 2C is an equivalent circuit diagram of the electronic components shown in FIG. 2A.

FIG. 3A illustrates the mechanism of position control for a functional cell of the electro-fluidic transport substrate 201 of FIG. 2A.

FIGS. 3B, 3C, 3D, 3E, and 3F illustrate an example of position control, in accordance with an embodiment of the present invention, using an external capacitance switching arrangement. FIG. 3G illustrates an example of position control using a voltage source to set phase charges directly, in accordance with an embodiment of the present invention.

FIG. 4 is a vertical section of a system 401, in accordance with an embodiment of the present invention, using a combination of a plurality of functional cells, of the type shown in FIGS. 2A, 2B, 2C and 3A, in a manner to provide a single layer of a larger system, where the forces from each of the droplets are combined to make a stronger actuator.

FIG. 5 is a vertical section of a stack of layers, in accordance with an embodiment of the present invention, wherein each layer is of the type shown in FIG. 4, and stacked in the same orientation as each other layer.

FIG. 6 is a vertical section of a stack of layers, in accordance with an embodiment of the present invention, wherein each layer is of the type shown in FIG. 4, and stacked with adjacent pairs which are oriented back-to-back.

FIG. 7 is a vertical section of a stack of a plurality of layers, in accordance with another embodiment of the present invention, again wherein each layer is of the type shown in FIG. 4, and wherein the spatial frequency of electrodes is different in each layer and configured to provide vernier adjustment of position.

FIGS. 8A and 8B are diagrams of linear and circular patterns, respectively, of the array of electrodes in an electro-fluidic transport substrate, in accordance with embodiments of the invention.

FIGS. 9A and 9B are top views of an x/y stator layer 131 and an x/y translation layer 133, respectively, of the type shown in FIG. 1A-C, in accordance with embodiments of the invention. FIG. 9C is a top view of a set of x/y translation layers 133 interlaced with a set of x/y stator layers 131, in accordance with embodiments of the invention. FIG. 9D is a vertical section of the set of x/y translation layers 133 interlaced with the set of x/y stator layers 131 shown in FIG. 9C, in accordance with embodiments of the invention.

FIGS. 10A and 10B are top views of an x/y stator layer and an x/y translation layer, respectively, assembled in an alternate configuration of the push-pull system, in accordance with one embodiment of the invention.

FIGS. 11A, 11B, and 11C are views corresponding to FIGS. 9A, 9B, and 9C, respectively, but in this case showing an embodiment of the rotational stage layers.

FIG. 12A is an exploded perspective view of an embodiment including a plurality of actuator stage 101 of the type shown in FIG. 1B, here are arranged in a grid, with the actuator stages attached to a rigid framework, in accordance with embodiments of the invention.

FIG. 12B is a cut-away view of the embodiment of FIG. 12A, revealing layer arrangements of two actuator stages, in accordance with embodiments of the invention.

FIGS. 12C, 12D, and 12E show an actuator stage 101 with a head extension on the top of workpiece-handling head 1215 for vacuum connection, with a plurality of actuator stages in FIGS. 12D and 12E, in accordance with another embodiment of the present invention.

FIG. 13 is a schematic showing an actuator stage 101 with a control box 108 configured to measure capacitances of the actuator stage to determine the position of a translation layer relative to a corresponding stator layer, in accordance with embodiments of the invention.

FIG. 14 shows a workpiece with alignment fiducials on a facet facing away from the actuator stage, wherein these fiducials are used to position the workpiece with respect to the actuator stage in accordance with an embodiment of the present invention.

FIG. 15 illustrates an embodiment in which alignment fiducials 1501 on the workpiece placement system 1502 and alignment fiducials 1503 on the destination structure 1504 are used to align the workpiece placement system to the destination structure.

FIG. 16 shows an embodiment in which a plurality of linear stages are stacked on top of each other in a long-range linear motion stage 1601 to achieve a higher speed movement over a distance.

FIG. 17 is a side view of a workpiece placement system 1702 receiving workpieces 1704 from component feeder 1703 and moving via global gantry system 1701 to allow placement of workpieces 1704 on a destination structure 1710 in accordance with an embodiment of the invention.

FIG. 18 is a side view of a workpiece placement system 1702, here illustrated as receiving workpieces 1704 from the multi-workpiece-transfer-module 1803; aligning the workpieces 1704 with imaging feedback provided by the multi-imager-module 1806; and bonding the workpieces 1704 to the target destination structure 1710 with the target-bonding-module 1812, all in accordance with an embodiment of the invention.

FIG. 19 is a flow-chart of a command sequence that may be executed by control box 1720 to cause performance of the workpiece placement steps illustrated in FIG. 17, in accordance with embodiments of the invention.

FIG. 20 is a flow-chart of a command sequence that may be executed by control box 1720 to cause performance of the workpiece placement steps illustrated in FIG. 18, in accordance with embodiments of the invention.

FIG. 21 is an illustration of command sequences executed by control box 1720 to cause a position change for a linear stage or a rotational stage, in accordance with embodiments of the invention.

### DETAILED DESCRIPTION OF SPECIFIC EMBODIMENTS

Definitions. As used in this description and the accompanying claims, the following terms shall have the meanings indicated, unless the context otherwise requires:

A “set” includes at least one member.

An “electro-fluidic transport substrate” includes:
a set of arrays of electrodes at a spatial frequency;
a dielectric layer, disposed over the set of arrays of electrodes and having a hydrophobic surface;
a fluidic layer disposed over the hydrophobic surface and including a first non-conductive liquid and a second conductive liquid, wherein the first and second liquids are immiscible; and
a carrier layer having defined hydrophilic and hydrophobic regions in selected contact with the second conductive liquid and the first non-conductive liquid, respectively, configured in a manner so that appropriate powering of the electrodes effectuates translation (motion) of the carrier layer.

An “actuator stage” is a component, of a transport system for causing translation of a workpiece placed thereon,

An “electro-fluidic actuator stage” is a component, of an electro-fluidic transport system for causing translation of a workpiece placed thereon, comprising (1) a base layer having a surface defining a z-axis normal to the surface, (2) a set of electro-fluidic transport substrates, and a (3) control port coupled to the electro-fluidic transport substrates.

A “hydrophobic surface” of a dielectric layer is a member selected from the group consisting of a hydrophobic finish included in the dielectric layer and a distinct hydrophobic layer disposed on the dielectric layer.

A “workpiece placement system” includes a structure having a plurality of actuator stages in a regular grid.

A current pulse is “shaped” to cause desired translation if it has a profile controlled over time to regulate an amount of charge delivered to each electrode in an array, so as to effectuate translation of a carrier layer in an electro-fluidic transport substrate in desired fractions of a spatial frequency of the array of electrodes.

As used herein, “control box” and “controller box” are synonymous with, and used interchangeably to refer to, a controller.

A “workpiece” may be a semiconductor die. As known in the art, a semiconductor die may be referred to simply as a die or a chip.

A “destination structure” may be a semiconductor substrate. As known in the art, a semiconductor substrate may be referred to as a substrate wafer.

In various embodiments of the present invention, there is provided a many-head parallel stage for an actuator that is configured to position many workpieces simultaneously, combining the simplicity and flexibility of die-bonders, with the parallelism of wafer-bonders, achieving both throughput gain and high precision.

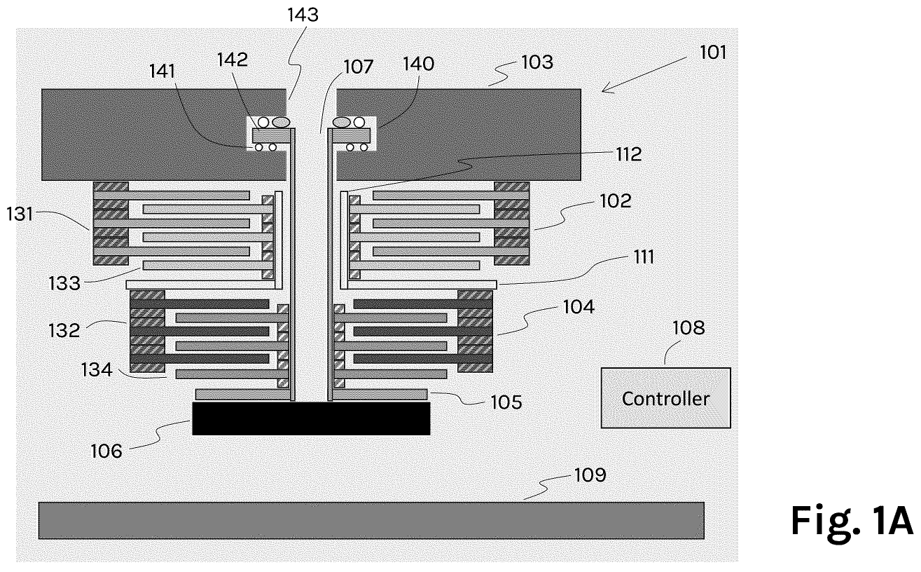

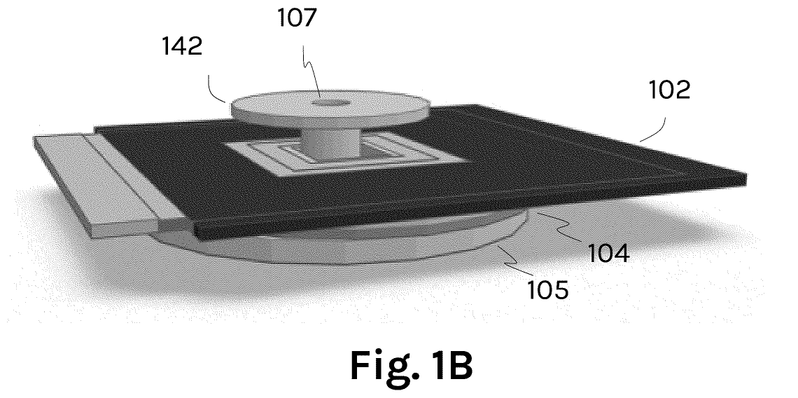

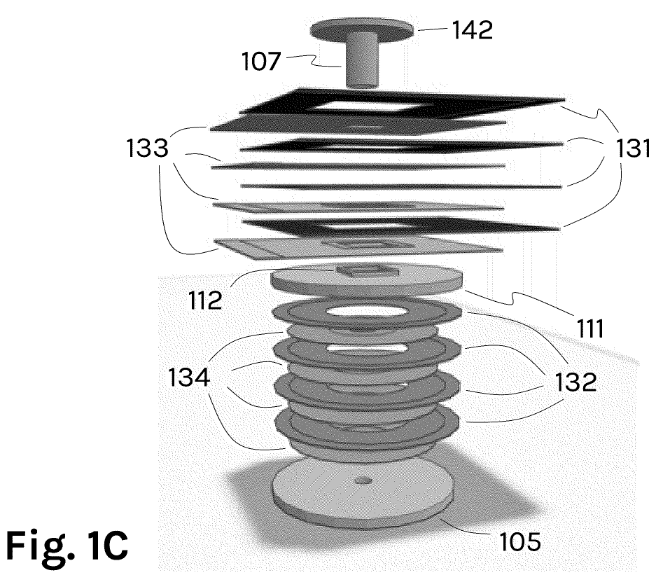

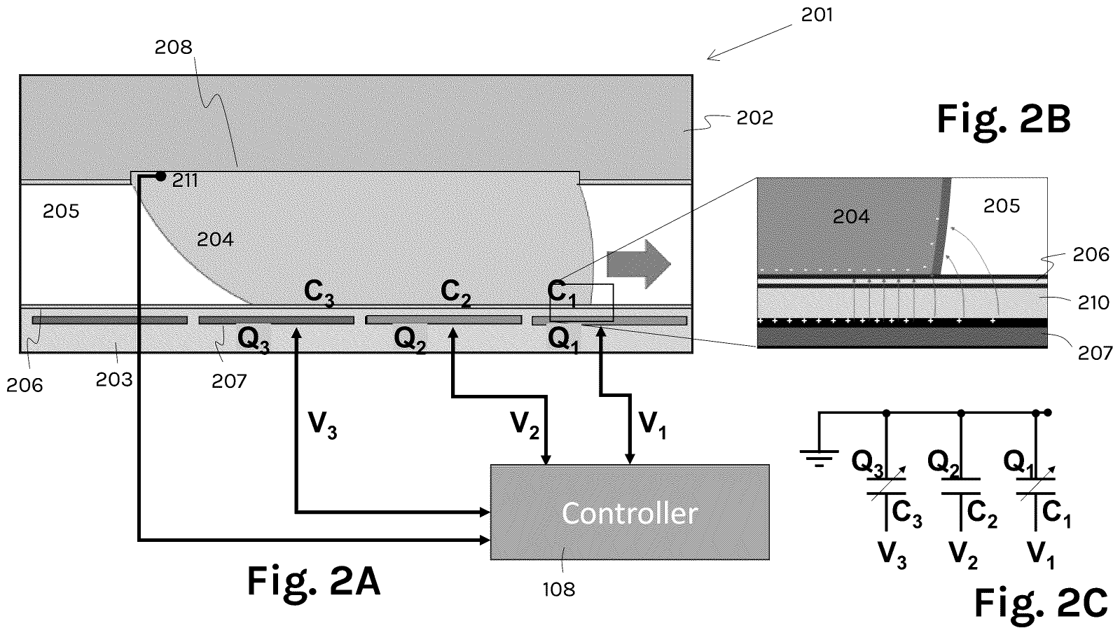

FIG. 1A is a vertical section view of the head 101 of an actuator stage 101 in accordance with an embodiment of the present invention. In this embodiment, the actuator stage includes an x/y-linear stage 102 (thus configured to achieve translation) having electro-fluidic transport substrates including interleaved stator layers 131 and translation layers 133, which are mounted on a base assembly 103. Attached to the x/y-linear stage 102 of the actuator stage is a rotational stage 104 having electro-fluidic transport substrates including interleaved stator layers 132 and rotor layers 134. The actuator stage further includes; a workpiece-handling head 105 attached to the rotational stage 104. In turn, vacuum tube 107, which is coupled to the workpiece-handling head 105 and mounted in the base assembly 103, feeds a vacuum to the handling head 105 in a manner to removably hold onto the head 105 a workpiece 106. A control box 108 is connected to the x/y-linear stage stator layers 131 and the rotational stage stator layers 132 to provide power and movement control. In one embodiment, to obtain position information of the workpiece 106 relative to the destination structure 109 onto which the workpiece 106 is to be placed, the control box 108 is configured to obtain and utilize capacitance data from the stages, as described below in connection with FIG. 2. The workpiece may be a semiconductor die and the destination structure may be a semiconductor substrate.

In the context of FIG. 1A, we refer to the Z axis as corresponding to the central axis Z-Z of the vacuum tube 107, and the X-Y axes as perpendicular to the Z axis.

In another embodiment, a gripper is used in place of the vacuum tube 0107 to removably adhere the workpiece 106 to the head 105. The workpiece may be a semiconductor die.

In a related embodiment, the control box 108 obtains position information from a camera configured to image appropriately situated fiducials to obtain relative positions of the workpiece 106 and the destination structure 109. In one embodiment, the fiducials are on the workpiece 106 and the actuator stage 101, while in another embodiment, the fiducials are placed on the actuator stage 101 and the destination structure 109 onto which the workpiece 106 is to be placed. The workpiece may be a semiconductor die and the destination structure may be a semiconductor substrate.

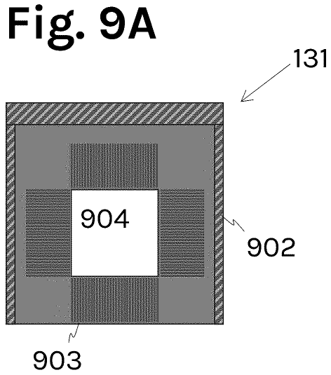

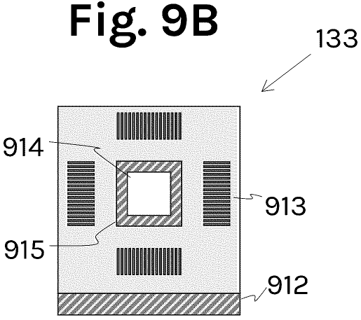

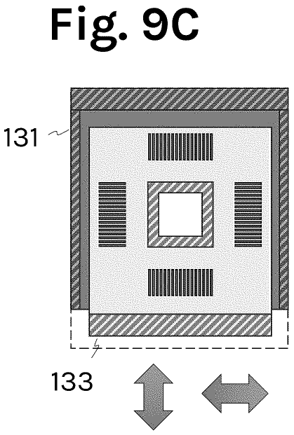

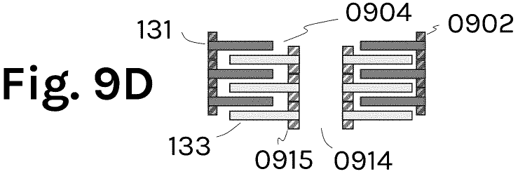

The base assembly 103 in FIG. 1A contains an opening 143 to which is coupled a vacuum supply. The vacuum tube 107 receives the vacuum from the opening 143. The vacuum tube 107 includes in its base a flange 142 that is mounted with ball bearings 141 in a corresponding slot 140. The handling head 105 is configured to slide and rotate within the slot 140 riding on ball bearings 141. To assure tight coupling between the opening 143 and the vacuum tube 107, the slot 140 is appropriately sealed, by means that may include vacuum grease, a set of O-rings, or both vacuum grease and a set of O-rings. As discussed above, the x/y linear stage 102 is composed of an electro-fluidic transport substrate, including a plurality of x/y stator layers 131, alternating with a plurality of x/y translation layers 133. The stator layers 131 are attached together along one or more outer edges as described in connection with FIG. 9, and, similarly, the translation layers 133 are attached together along one or more outer edges and one or more inner edges as described in connection with FIG. 9.

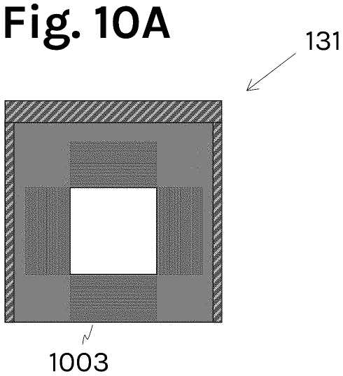

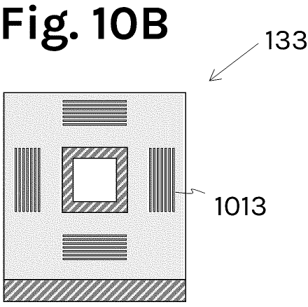

A mounting plate 111 has a core 112 that is fitted into the central opening of the translation layers 133 and around the vacuum tube 107. The rotational stage 104 is attached to the mounting plate 111. As described above, the rotational stage 104 is composed of another electro-fluidic transport substrate, including a plurality of rotational stator layers 132, alternating with a plurality of rotor layers 134. The rotational stator layers 132 are attached together along the other edges as described in connection with FIG. 10. The rotor layers 134 are attached together along the inner edges as described in connection with FIG. 10. The workpiece-handling head 105 is attached to the rotor layers 134. The workpiece may be a semiconductor die.

As described above, in one embodiment, a workpiece 106 is attached to the workpiece-handling head 105 by the vacuum introduced through vacuum tube 107. The workpiece may be a semiconductor die.

In another embodiment, a workpiece 106 is attached to the workpiece-handling head 105 via polymer coating on the surface of 105. The workpiece may be a semiconductor die.

In another embodiment, a plurality of slots 140 and corresponding flanges 142 are used for added stability.

The control box 108 sends a first category of electrical signals to the x/y-translation layers 133 to move linearly in x and y with respect to the x/y-stator layers 131, thereby causing the workpiece-handling head 105 and the workpiece 106 to move correspondingly in x and y. The control box 108 sends a second category of electrical signals to the rotor layers 134 to cause them to be angularly displaced about the Z axis, thereby causing the workpiece-handling head 105 and the workpiece 106 to be correspondingly angularly displaced. The workpiece may be a semiconductor die.

In FIG. 1B, a perspective rendering of some of the actuator stage components of FIG. 1A is shown, including the workpiece-handling head 105, the x/y linear stage 102, the rotational stage 104, the flange 142, and the vacuum tube 107. The workpiece may be a semiconductor die.

FIG. 1C shows an exploded view of the various layers discussed in relation to FIG. 1A. The x/y linear stator layers 131 and the x/y translation layers 133 form the x/y linear stage 102 of FIG. 1A. The rotational stator layers 132 and the rotor layers 134 form the rotational stage 104 of FIG. 1A. A few layers are illustrated for clarity. In actual embodiments, the number of actuating layers will be determined by the application requirement.

Alternative configurations can be built to provide equivalent movement of the workpiece in-plane, for example, one rotational stage, with one linear stage, with a second rotational stage; or one single-axis linear stage, with a second single-axis linear stage oriented in a different direction, with a rotational stage; etc. The workpiece may be a semiconductor die.

FIG. 2A is a vertical section of one embodiment of a functional cell of an electro-fluidic transport substrate 201 in accordance with an embodiment of the present invention. FIG. 2B is an enlarged view of the right end corner of the droplet 204 of FIG. 2A.

The transport substrate functional cell is composed of a rotor/translation layer 202, where a conductive liquid droplet 204 is anchored to a well 208 either physically or chemically. The conductive liquid droplet 204 is surrounded by another immiscible non-conductive liquid 205 and is free to glide across the hydrophobic surface layer or finish 206 of the stator layer 203. The conductive liquid droplet 204, the surrounding liquid 205, and the hydrophobic layer 206 are chosen such that electro-wetting effect is possible. As a voltage is applied across the interface between the conductive liquid droplet 204 and the hydrophobic layer 206, it changes the contact angle between the conductive liquid droplet 204, the non-conductive liquid 205, and the hydrophobic layer 206.

In another embodiment, the liquid droplet 204 is non-conductive, while the surrounding liquid 205 is conductive, in which case the voltage is applied across the surrounding liquid 205 and the hydrophobic layer 206.

In another embodiment, the liquid droplet 204 is surrounded by air or an inert gas 205.

The stator layer 203 has embedded electrodes 207. The liquid droplet 204 is connected to an electrode 211, either via direct contact or capacitive coupling somewhere along the droplet outside the cross-sectional view. The control box 108 regulates the amount of charge in each of the embedded electrode 207 and the liquid droplet 204 via the electrode 211. Each electrode forms a capacitor with the liquid droplet across the dielectric 210, as shown in FIG. 2B, a close-up view of the right-hand corner of the droplet 204. The relative position of the liquid droplet and the electrode determines the capacitance. It is the highest when the electrode is entirely under the droplet, and reduces in value as the droplet only partially covers the electrode. The capacitance (C), together with the charges on the electrode (Q), determine the voltage across that electrode and the water droplet (V), according to V=Q/C.

The equivalent circuit of the electrodes and the capacitors they form with the droplet 204 is shown in FIG. 2C. In one embodiment, the liquid droplet 204 is grounded, and three of the electrodes are provided charges Q1, Q2, and Q3, as in FIG. 2A. The position of the droplets with respect to the electrodes results in the electrodes forming capacitances C1, C2, and C3 with respect to the ground, leading to voltages V1, V2, and V3 at the respective electrodes. In the example illustrated in FIG. 2A, V1 is larger than V3, resulting in a smaller contact angle on the right-hand side as compared to the left-hand side of the droplet 204, leading to a net force moving the droplet 204 and the rotor layer 202 to the right, as indicated by the arrow pointing to the right.

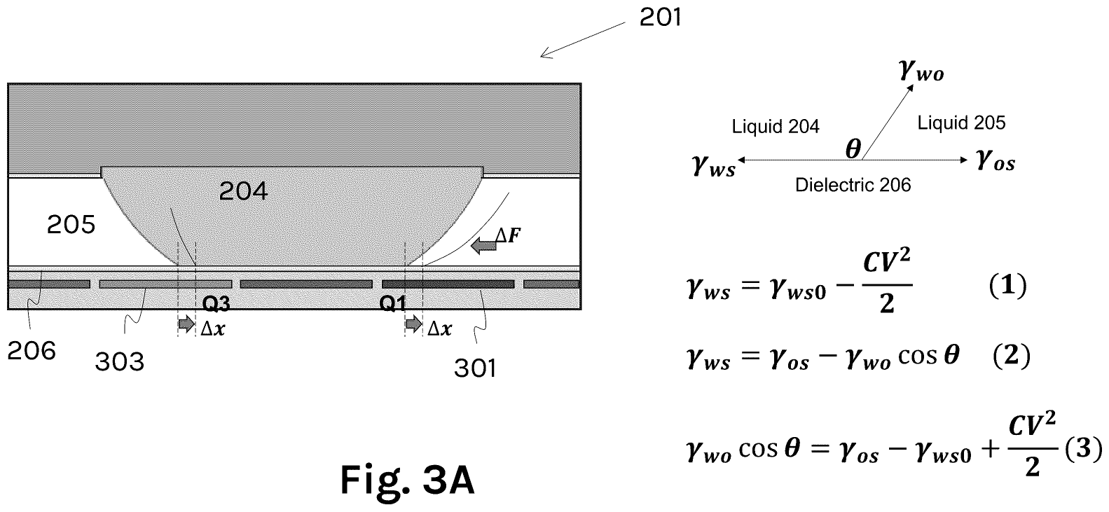

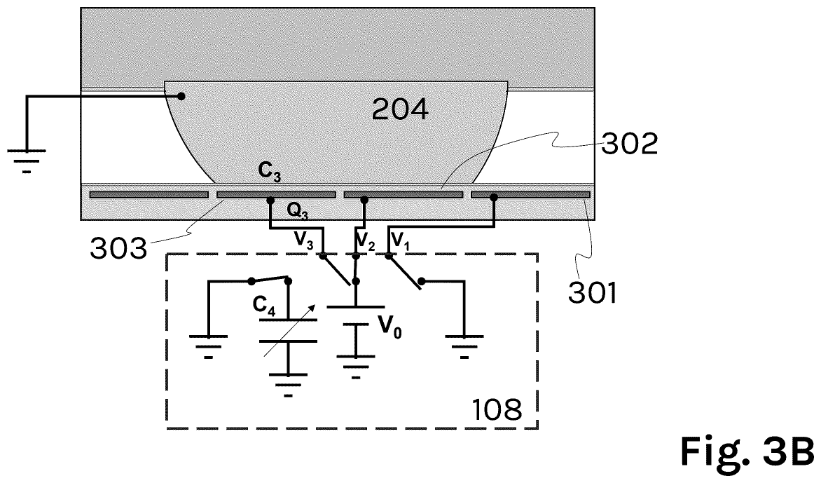

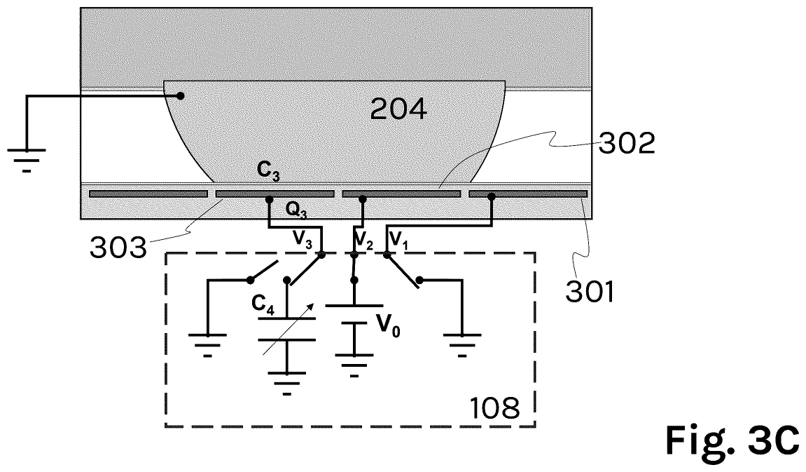

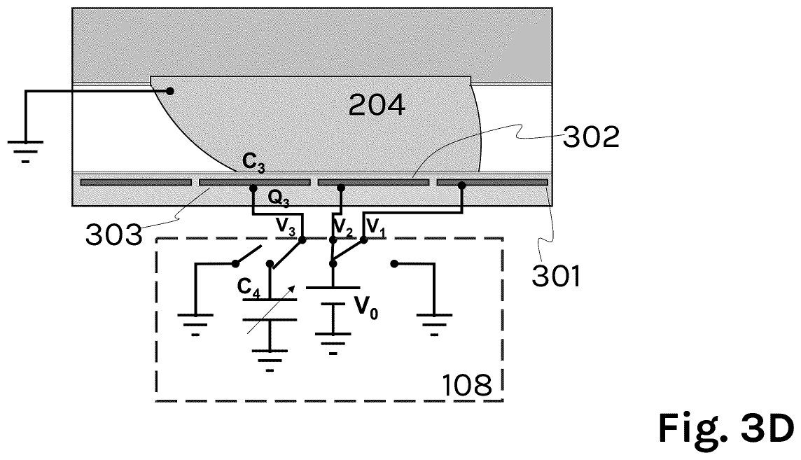

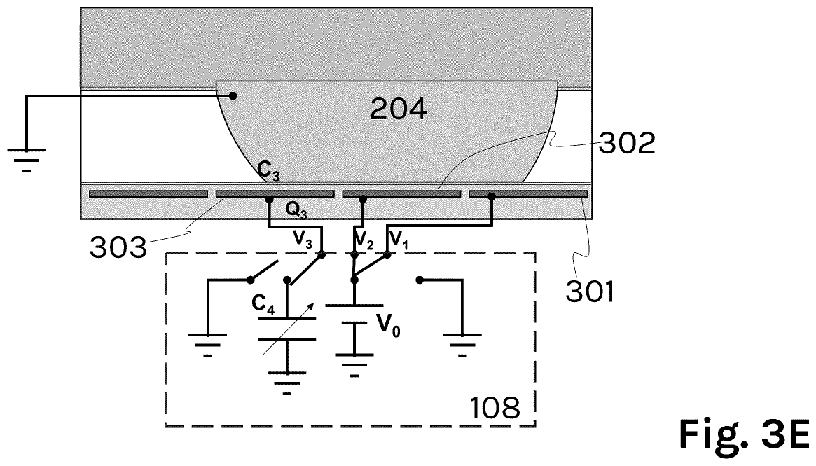

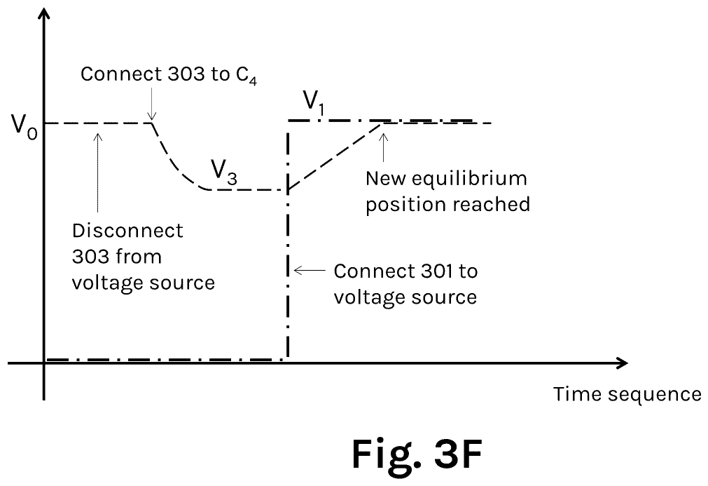

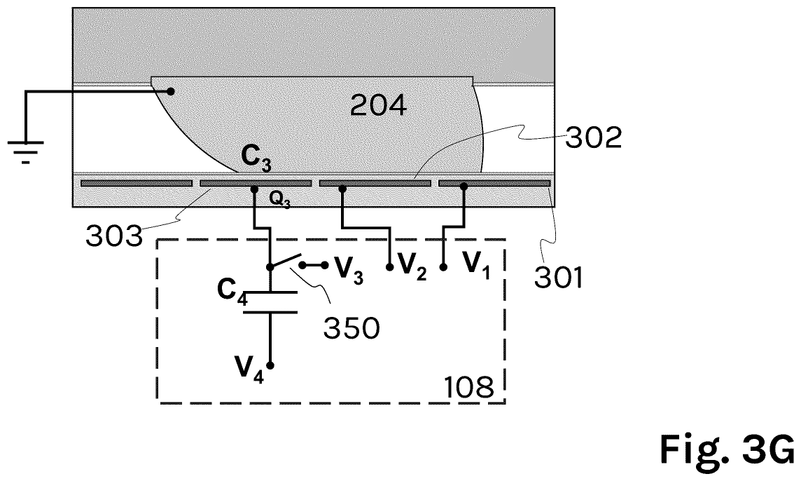

FIG. 3A illustrates the mechanism of position control for a functional cell of the electro-fluidic transport substrate 201 of FIG. 2A. The liquid droplet 204 touches the stator dielectric surface 206 on top of an array of electrodes. The left liquid-dielectric interface is on top of electrode 303. The right liquid-dielectric interface is on top of electrode 301. The contact angle θ of the droplet of liquid 204 with the stator dielectric surface 206 is determined by the voltages across these two electrodes to the liquid droplet, respectively, as given by the equations (1), (2), (3) in FIG. 3A. γ_{ws} is the surface tension between liquid 204 and dielectric surface 206. It is related to γ_{ws0}, the surface tension without applied voltage, by equation (1). C is the capacitance per unit area at the interface. V is the applied voltage. γ_{wo} is the surface tension between liquid 204 and liquid 205. γₒₛ is the surface tension between liquid 205 and dielectric 206. Higher voltage leads to smaller contact angle as in equation (3). If the contact angles on the left side and the right side are different, there is a net force from the surface tensions, pushing the droplet toward the side with the smaller contact angle, which is also the side with the higher voltage.

In the example illustrated in FIG. 3A, the droplet 204 is in equilibrium with the contact angles being the same on the left and the right interfaces. As in FIG. 2A, let us designate the capacitance attributable to the presence of liquid 204 above electrode 303 as C3, and the voltage across electrode 303 to the droplet 204 as V3, with Q3 designating the charge on the C3 capacitor. Similarly, let us designate the capacitance attributable to the presence of liquid 204 above electrode 301 as C1, and the voltage across electrode 301 to the droplet 204 as V1, with Q1 designating the charge on the C1 capacitor. Therefore, the voltage across electrode 303 to the droplet 204, V3=Q3/C3, is equal to the voltage across electrode 301 to the droplet 204, V1=Q1/C1. The capacitance is roughly proportional to the overlap between the droplet and the electrode. If the droplet 204 is moved to the right by a distance Δx while the charges are maintained on the electrodes 301 and 303, the capacitance C3 is reduced, because less liquid 204 overhangs electrode 303, leading to an increase in V3. At the same time, the capacitance C1 increases, leading to a reduction in V1. From the previous discussion, it is clear that there is now a restoring force ΔF pushing the droplet back to the left, until the equilibrium position is attained once more with V1 equal to V3.

The droplet 204 is in equilibrium when V1=V3, which can also be written as Q1/C1=Q3/C3. Since the capacitances C1 and C3 are correlated by the position of the droplet 204 on the dielectric surface 206, the equilibrium position is determined by the charge ratio Q1/Q3. The accuracy of the position is determined by the accuracy of this charge ratio.

In related embodiment, a mixed voltage/charge control can be applied, in which the controller box 108 regulates voltage at one side of the droplet 204, for example V1, and regulates charge at the other side of the droplet, for example Q3. In this case, as discussed in the previous paragraph, the rightward movement of the droplet will reduce the capacitance C3, and thus increase V3=Q3/C3, so as to provide a restoring force as V3 deviates from V1.

FIGS. 3B, 3C, 3D, 3E, and 3F illustrate an example of position control, in accordance with an embodiment of the present invention, using an external capacitance switching arrangement. In this embodiment, the charge regulation is accomplished by connecting an external capacitor in parallel with one of the phases. For example, in reference to FIG. 3B, let the initial configuration be such that electrode 301 is grounded, and electrodes 302 and 303 are connected to the voltage source with value of V0, so the droplet sits on top of electrodes 302 and 303 in FIG. 3B. The capacitor C3 has its maximum capacitance value of C0. Therefore, the charge on capacitor C3 is given by Q3=C3×V3=C0×V0. To cause the droplet 204 to move, electrode 303 is first disconnected from the voltage source, and then connected to an external capacitor with capacitance value of C4 and zero charge. The effect of this action is to connect capacitor C3 in parallel with capacitor C4. (These actions can be effectuated by suitable configuration of the control box 108, as illustrated in FIG. 3C.) Part of the charge on capacitor C3 will move to the external capacitor C4 to equilibrate voltages of these two capacitors, leading to a new V3 that is lower than the original value of V0. Next, V1 is disconnected from ground and connected to voltage source V0. (Also effectuated by suitable configuration of the control box 108, as illustrated in FIG. 3D.) This action will cause the force to move the droplet. since V3 is lower than V1. Capacitance C3 drops as the droplet moves until V3 is equal to V1. The end condition is therefore given by C0×V0/(C4+C3)=V0, or C3=C0−C4, as illustrated in FIG. 3E. By choosing the capacitance value C4 of the external capacitor, the final value of C3 can be determined, and so is the position of the droplet 204. The trajectories of V1 and V3 in response to the control changes described in this example are illustrated in FIG. 3F.

FIG. 3G illustrates an example of position control using a voltage source to set phase charges directly, in accordance with an embodiment of the present invention. In this example, voltages of various phases (V1, V2, V3) are controlled by the control box 108. The phase associated with voltage V3 is shown in more detail where phase electrode 303 may be disconnected from voltage source V3, via an electronic switch or isolator 350. Electrode 303 is connected with measurement capacitor C4. The charge on the electrode 303 can be tuned by varying V3 when 350 is connected. Once 350 is disconnected, V1 can be varied to pull droplet 204 to different positions, subject to C3=(Q3−(V1−V3)C4)/V1. C3 being capacitively connected to V4 via C4 also allows it to be measured and monitored.

There could be static friction associated with the liquid-stator interface. It would result in an offset of the position as compared to what the charge ratio would suggest. This offset can be compensated. It can also be measured via a position measurement system.

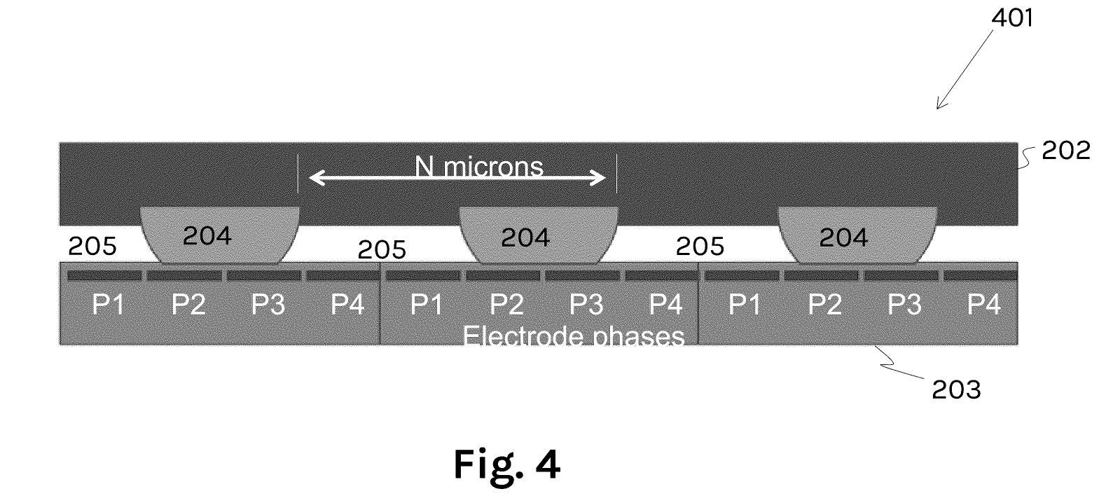

FIG. 4 is a vertical section of a system 401, in accordance with an embodiment of the present invention, using a combination of a plurality of functional cells, of the type shown in FIGS. 2A, 2B, 2C and 3, in a manner to provide a single layer of a larger system, where the forces from each of the droplets are combined to make a stronger actuator. The droplets 204 are anchored to the rotor/translation layer 202, and are separated by N microns between them. In one embodiment, N is 40. The droplets 204 slide on top of the stator layer 203 with the embedded electrodes. In one embodiment, the electrodes are organized into four phases, P1, P2, P3, P4. The electrodes of each phase are charged and discharged together. The droplets 204 are surrounded by the other liquid 205.

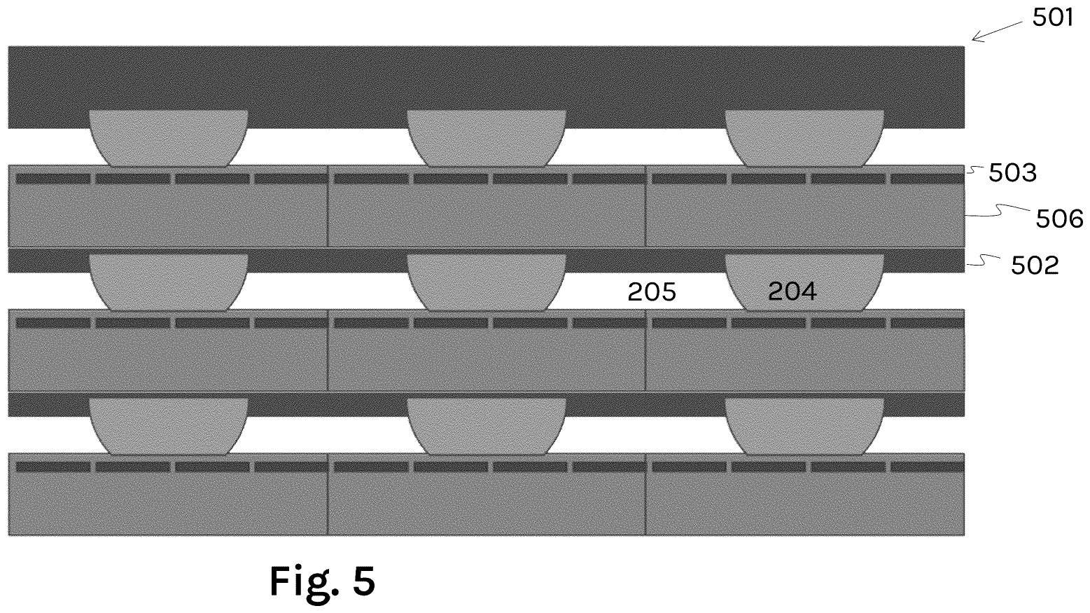

FIG. 5 is a vertical section of a stack of layers, in accordance with an embodiment of the present invention, wherein each layer is of the type shown in FIG. 4, and stacked in the same orientation as each other layer. In this configuration, each layer 506 has a top surface 503 where the droplets 504 contact and slide against, on top of embedded electrodes. The layer 506 has a bottom surface 502 with wells where the droplet 204 are anchored to. In this embodiment, each layer 506 with its anchored droplets 204 slides against the next layer either in the same direction which increases the speed of movement, or in alternating directions which increase the total force output of the electro-fluidic transport substrate 501. The droplets 204 are surrounded by the other liquid 205.

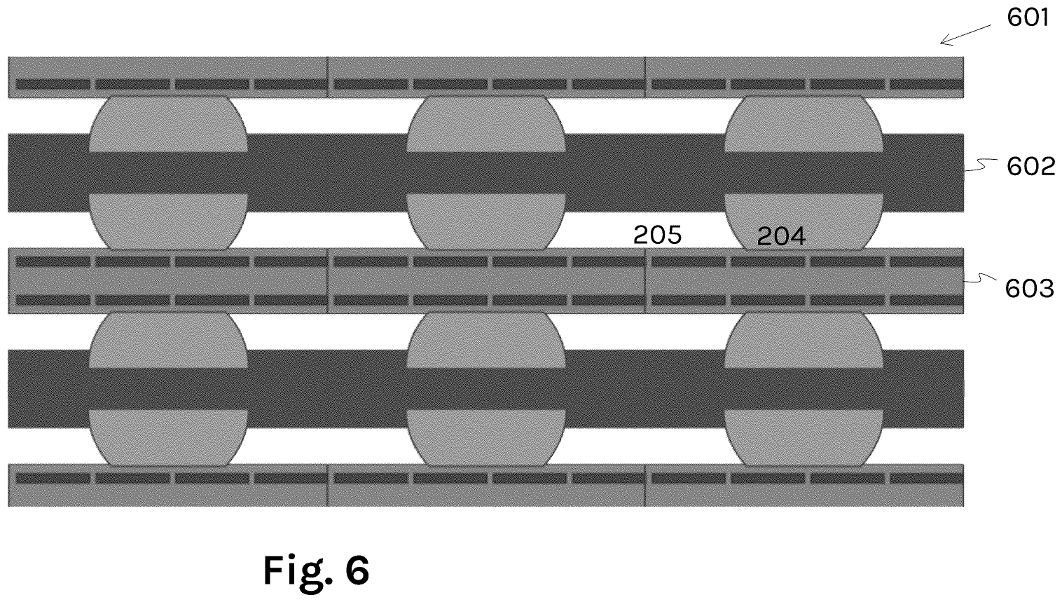

FIG. 6 is a vertical section of a stack of layers, in accordance with an embodiment of the present invention, wherein each layer is of the type shown in FIG. 4, and stacked with adjacent pairs which are oriented back-to-back. In this configuration, the electro-fluidic transport substrate 601 is composed of two types of layers—the rotor/translation layer 602 where both top and bottom surfaces have wells where droplets 204 are anchored in, and the stator layer 603 where both top and bottom surfaces have embedded electrodes and are in contact with droplets 204. The droplets 204 are surrounded by the other liquid 205.

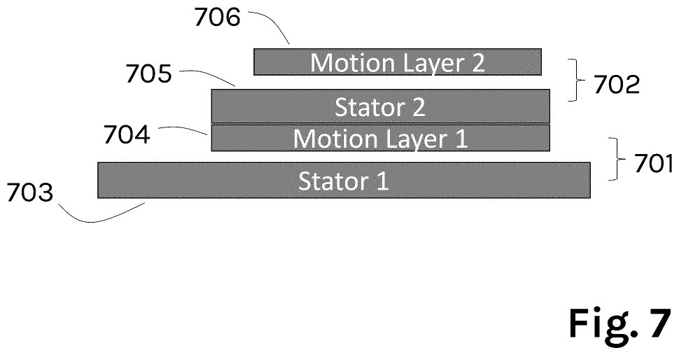

FIG. 7 is a vertical section of a stack of a plurality of layers, in accordance with another embodiment of the present invention, again wherein each layer is of the type shown in FIG. 4, and wherein the spatial frequency of electrodes is different in each layer and configured to provide vernier adjustment of position. Two electro-fluidic transport substrate layers (as shown in FIG. 4) are stacked on top of each other. The top electro-fluidic transport substrate 702 has a pitch (distance from droplet to droplet) of N2, whereas the bottom electro-fluidic transport substrate 701 has a pitch of N1. The electro-fluidic transport substrate 701 has a stator layer 703, and a translation layer (motion layer) 704. The electro-fluidic transport substrate 702 has a stator layer 705, and a translation layer (motion layer) 706. The stator layer 702 is attached to the translation layer 704. When N1 is not equal to N2, a finer resolution given by N3 equal to the greatest common divider of N1 and N2 can be achieved for the system. For example, if N1=40 um, and N2=39 um, then 1 um step can be achieved by moving the electro-fluidic substrate 701 one step forward and the electro-fluidic transport substrate 702 one step backward.

Another way to achieve an effect similar to that accorded by the configuration of FIG. 7 is to have the droplets pitch be slightly different from an integer multiple of the electrode pitch.

FIG. 5, FIG. 6 and FIG. 7 show alternative embodiments of how a plurality of layers of the electro-fluidic transport substrate can be stacked in the Z direction.

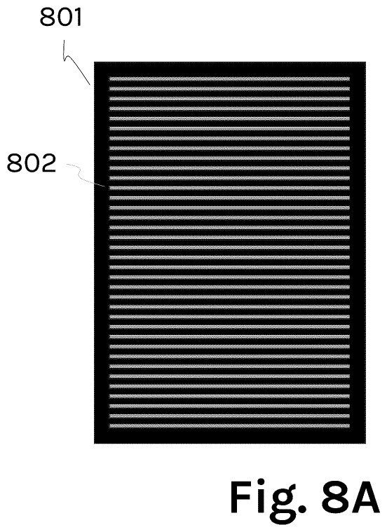

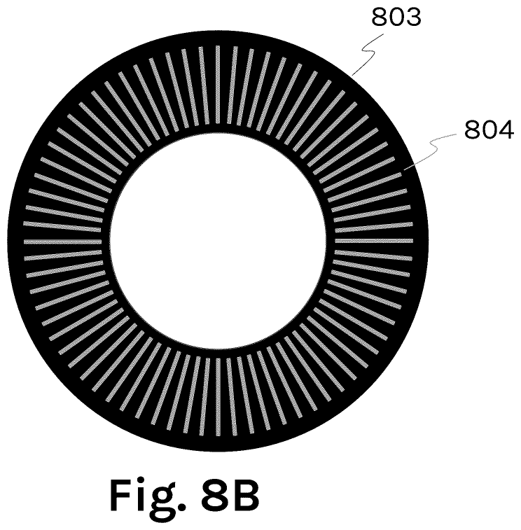

FIGS. 8A and 8B are diagrams of linear and circular patterns, respectively, of the array of electrodes in an electro-fluidic transport substrate, in accordance with embodiments of the invention. We have mentioned above that an actuator in accordance with an embodiment of the present invention utilizes a set of electro-fluidic transport substrates, disposed on the base layer, wherein each of the substrates has an array of electrodes. In FIG. 8A and FIG. 8B, are illustrated alternative embodiments of this array, and therefore how the unit cells of the electro-fluidic transport substrate can be arranged in the X-Y plane. In FIG. 8A, the translation layer 801 is displayed with the droplets 802 arranged in a linear fashion. These are matched with stator with embedded electrodes also arranged in the linear fashion to form linear actuators to achieve translation of the head of the transport substrate. In FIG. 8B, the rotor layer 803 is displayed with the droplets 804 arranged in a circular pattern. These are matched with stator layer with embedded electrodes also arranged in a circular pattern, to achieve rotation of the head of the transport substrate.

FIGS. 9A and 9B are top views of an x/y stator layer 131 and an x/y translation layer 133, respectively, of the type shown in FIG. 1A-C, in accordance with embodiments of the invention. Referring to FIG. 9A, x/y-stator layer 131 includes four embedded electrode arrays 903 arranged around central opening 904. Along three edges of x/y stator layer 131 are thick regions 902, which are used to (i) bond a plurality of x/y-stator layers 131 together, e.g., as shown in FIG. 9D, (ii) bond an x/y-stage to the base assembly 103 of FIG. 1A, and (iii) connect electrode arrays 903 to external power and control circuits.

Referring to FIG. 9B, x/y-translation layer 133 includes four droplet arrays 913, each array positioned to align with a corresponding set of electrode arrays 903 to form an electro-fluidic transport substrate. The center of the x/y-translation layer 133 includes center thick region 915 defining opening 914. Along one edge of x/y translation layer 133 is second thick region 912. The center thicker region 915 fits within opening 904 of x/y-stator layer 131. Center thick region 915 and second thick region 912 are used to bond a plurality of x/y-translation layers 133 together, and to bond x/y-stage translation layers to a payload.

FIG. 9C is a top view of a set of x/y translation layers 133 interleaved with a set of x/y stator layers 131, in accordance with embodiments of the invention. FIG. 9D is a vertical section of the set of x/y translation layers 133 interlaced with the set of x/y stator layers 131 shown in FIG. 9C, in accordance with embodiments of the invention. Thicker regions 902, 912 and 915 serve to connect individual layers and connect to the base assembly 103 substrate and a payload, respectively, while allowing relative motion between the x/y stator layers 131 and x/y translation layers 133. In describing motion achieved by the translation layer 133 in relation to the stator layer 131, we refer to left/right motion in FIG. 9C as along the x-axis of the x/y plane and up/down motion in FIG. 9C as along the y-axis of the x/y plane. Two electrode arrays 903 of x/y stator layer 131 (shown at the top and bottom of FIG. 9A) move translation-layer 133 left and right with respect to stator layer 131. Two electrode arrays 903 of x/y stator layer 131 (shown at the left and right of FIG. 9A) move translation-layer 133 up and down. In some embodiments, an axle connects translation layers 133 via central opening 914.

FIGS. 10A and 10B are top views of an x/y stator layer and an x/y translation layer, respectively, assembled in an alternate configuration of the push-pull system of FIGS. 9A and 9B, in accordance with another embodiment of the invention. In FIGS. 10A and 10B, the interactions between electrode arrays and droplet arrays are configured to achieve motion along the x-axis and y-axis in a manner wherein the axes are swapped in relation to the motion achieved in FIGS. 9A and 9B. In other embodiments, any combination of electrode arrays can be configured to move along either the x-axis or the y-axis, and additional electrodes arrays and droplet arrays can be added to a corresponding layer.

The figures in this application are illustrative and are not intended to show dimensions to scale.

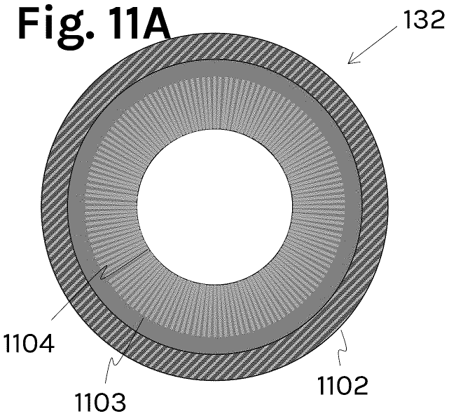

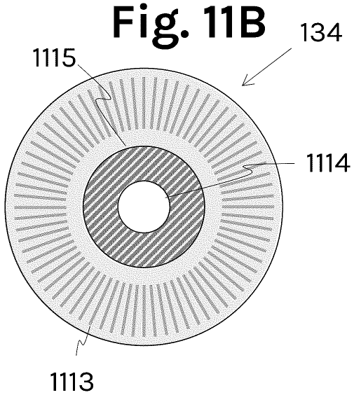

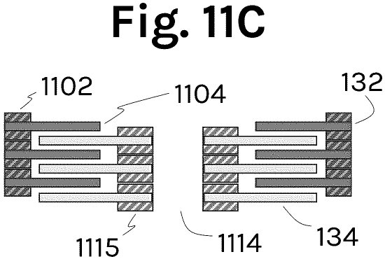

FIGS. 11A, 11B, and 11C are views corresponding to FIGS. 9A, 9B, and 9C, respectively, but in this case showing an embodiment of the rotational stage layers. The stator layer 132 is illustrated in FIG. 11A in a top view, showing a circular array of embedded electrodes 1103 arranged around a central opening 1104. Along the outer edge is a thicker region 1102 used to bond a plurality of stator layers 132 together, and for bonding the rotational stage to the base layer, and for connecting electrodes 1103 to external power and control circuits. The rotor layer 134 is illustrated in FIG. 11B in a top view, having a droplet array 1113 arranged to match the electrode array 1103 to form an electro-fluidic transport substrate. The center of the rotor layer 134 has a thicker region 1115 with an opening 1114. The thicker region 1115 fits within the opening 1104 in the stator layer 132. The thicker region 1115 is used to bond a plurality of rotor layers together, and for bonding the rotational stage to payloads. The assembled configuration with the rotor layers 134 interlaced with the stator layers 132 is illustrated in FIG. 11C in a vertical section. Thicker regions 1102 and 1115 serve to connect the individual layers and connect to substrate and payload, while allowing relative motion between the stator layers 132 and the rotor layers 134.

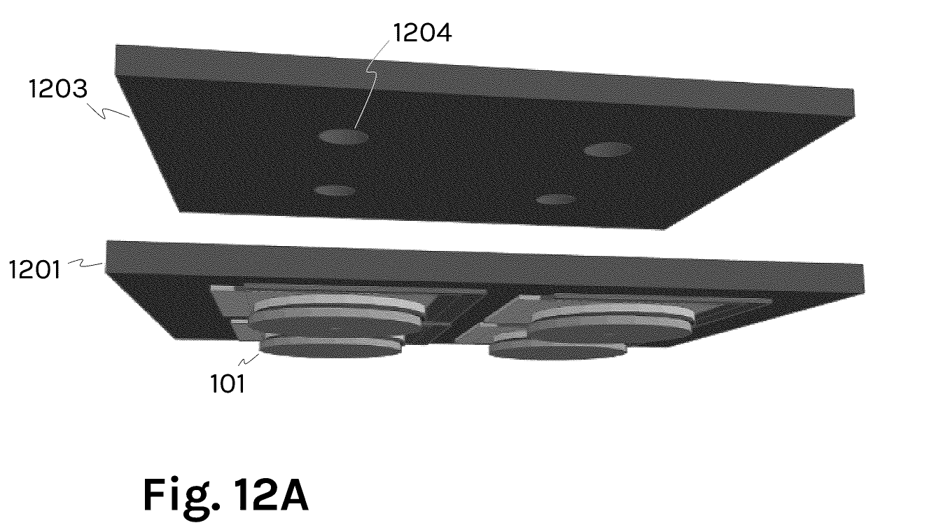

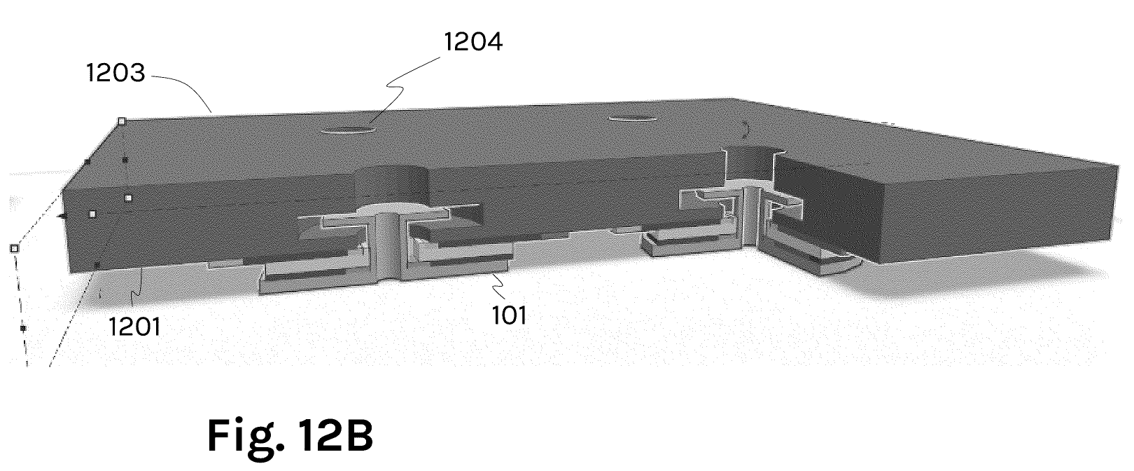

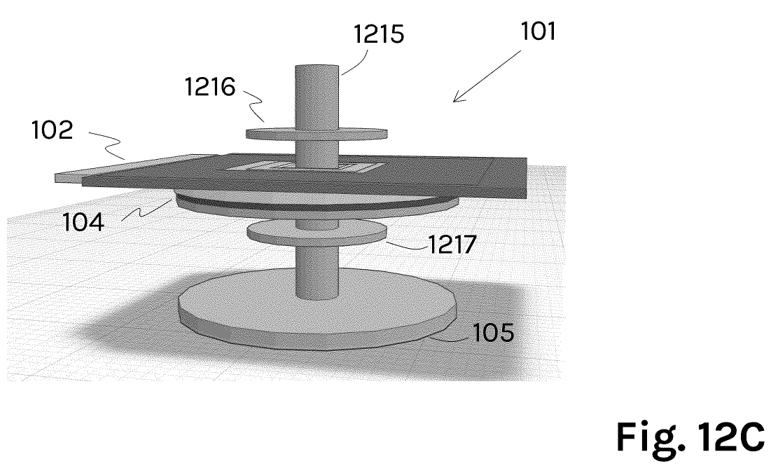

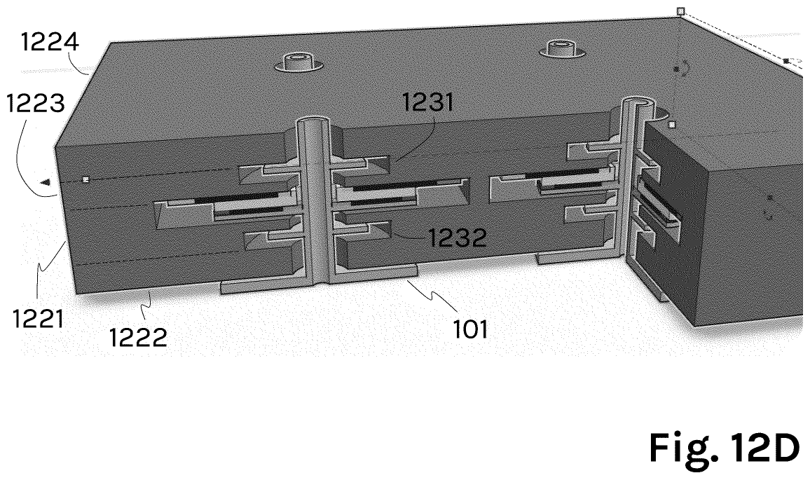

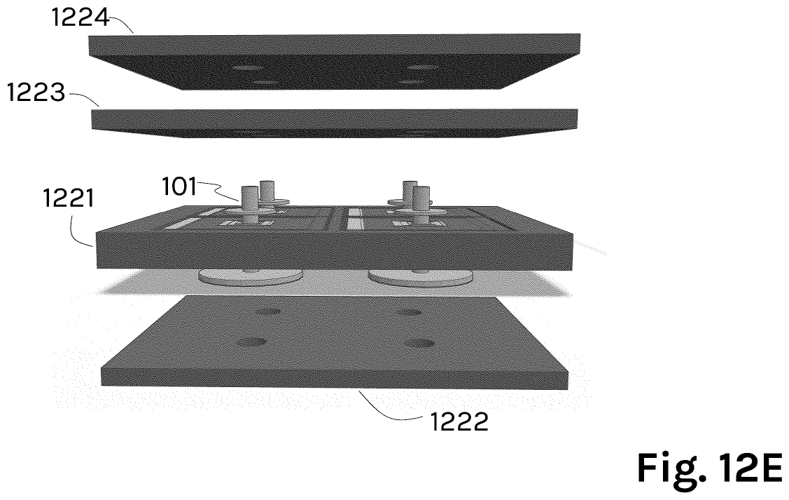

FIG. 12A is an exploded perspective view of an embodiment including a plurality of actuator stages 101 of the type shown in FIG. 1B, here arranged in a grid, to a plurality of workpieces to be placed simultaneously, forming a workpiece-placement system. Each actuator stage 101 is attached to substrate 1201 via its x/y linear stage 102. Top cover 1203 attaches to the top of the substrate 1201 with matching vacuum connection 1204 for each actuator stage 101. Together, substrate 1201 and top cover 1203 form a rigid framework to which the actuator stages are attached. The workpiece may be a semiconductor die.

FIG. 12B is a cut-away view of the embodiment of FIG. 12A, revealing layer arrangements of two actuator stages, in accordance with embodiments of the invention.

Different configurations of the workpiece-handling head are possible. In another embodiment, the workpiece placement system shown in FIGS. 12C, 12D, and 12E, the actuator stage 101 has one head extension on the top of workpiece-handling head 1215 for vacuum connection. The actuator stage 101 has a x/y linear stage 102 and a rotational stage 104, and a workpiece attachment head 105, in the same manner as shown in FIG. 1B. There is a position plate 1216 which sits in the slot 1231 of the substrate plate after assembly. There is a second position plate 1217 which sits in the slot 1232 of the substrate plate after assembly. In this embodiment, the actuator stage 101 is supported by a plurality of supporting plates. The workpiece may be a semiconductor die.

The actuator layers are enclosed by a plurality of supporting plates. In one embodiment, the actuator stage 101 is attached to plate 1223. The plate 1221 is attached to the bottom of 1223, and the position plate 1217 is attached to the bottom of the workpiece handling head 1215. The plate 1222 is attached to the bottom of 1221, and the workpiece attachment head 105 is attached to the bottom of the position plate 1217. The position plate 1216 is attached to the top of the workpiece handling head 1215. The plate 1224 is attached to the top of the plate 1223, completing the assembly of the workpiece placement system. The workpiece may be a semiconductor die.

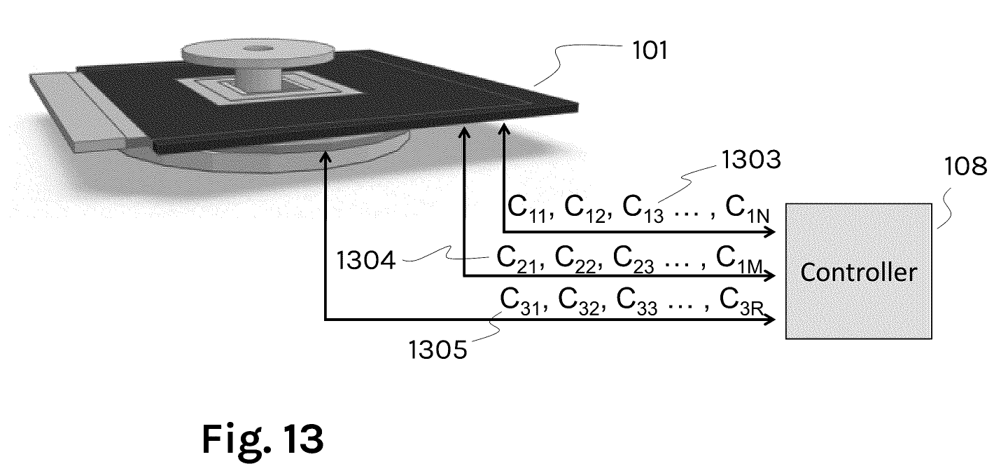

FIG. 13 is a schematic showing an actuator stage 101 with a control box 108 configured to measure capacitances of the actuator stage to determine the position of a translation layer relative to a corresponding stator layer, in accordance with embodiments of the invention. As a droplet slides over an embedded electrode of an array, the capacitance of the capacitor formed between the electrode and the droplet changes depending on the amount of overlap. By measuring this capacitance, the amount of overlap, and therefore the position of the moving translation layer relative to its corresponding stator layer can be determined. In one embodiment, a capacitance measurement is performed on position-driving electrodes using an AC signal with a frequency higher than that of the control signals used to regulate the amount of charge, or voltage on the electrodes. In another embodiment, a capacitance measurement is performed on dedicated position-measurement electrodes and associated droplets. In one embodiment, control box 108 measures three sets of capacitances, with electrode phases 1303 associated with movement along one of the x-axis and the y-axis of a linear stage, electrode phases 1304 associated with movement along the other one of the x-axis and y-axis of the linear stage, and electrode phases 1305 associated with angular rotation of a rotational stage.

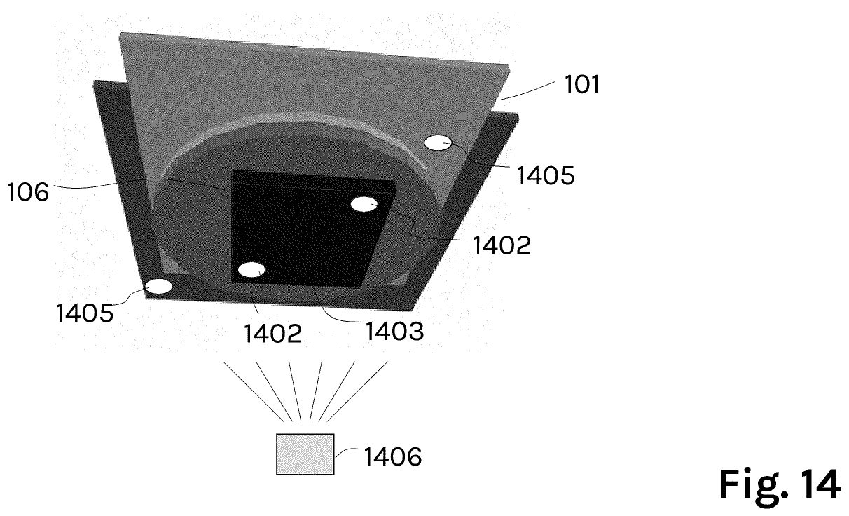

FIG. 14 shows a workpiece with alignment fiducials on a facet facing away from the actuator stage, wherein these fiducials are used to position the workpiece with respect to the actuator stage in accordance with an embodiment of the present invention. Workpiece 106 has alignment fiducials 1402 on the facet 1403 to be bonded with a substrate. The actuator stage 101 has alignment fiducials 1405. Workpiece position camera 1406 takes pictures of the actuator stage 101 with component workpiece 106 so that fiducials 1402 and 1405 are in the same pictures, and are used to calculate the position of the component workpiece 106 with respect to the actuator stage 101. In another embodiment, a plurality of workpiece position cameras are used to take pictures of various groups of fiducials. The calculated position of the component workpiece 106 is used to move the actuator stage to position the workpiece to the desired position. The workpiece may be a semiconductor die.

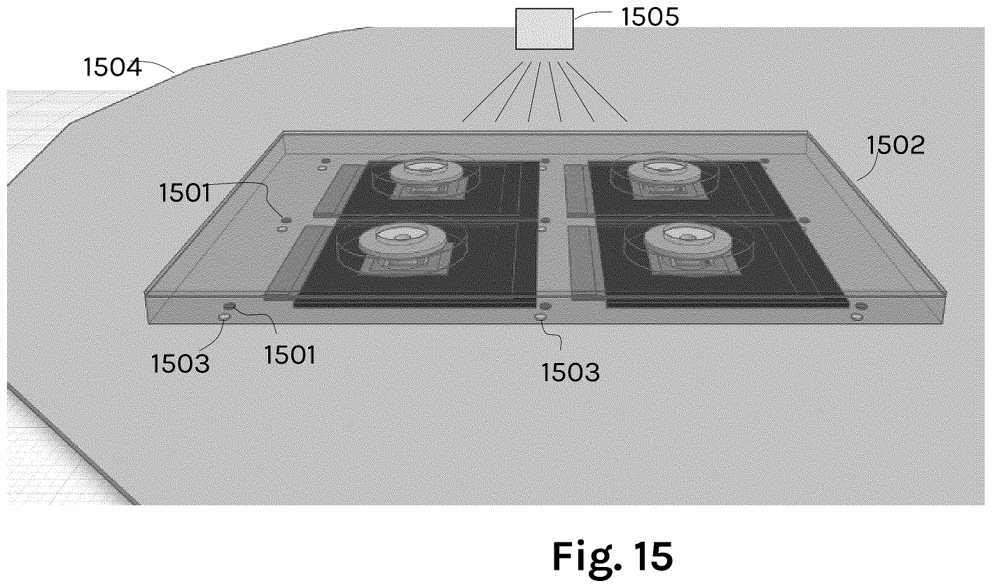

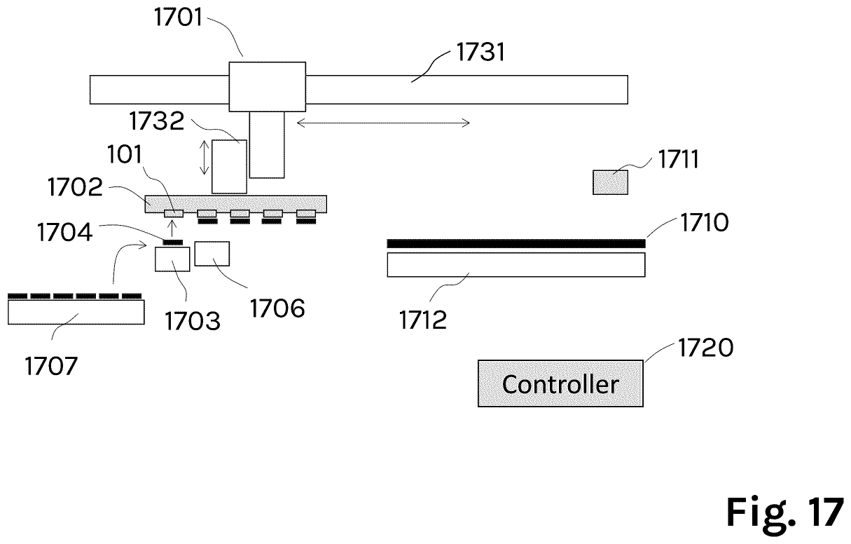

As illustrated in FIG. 15, in one embodiment, alignment fiducials 1501 on the workpiece placement system 1502 and alignment fiducials 1503 on a destination structure 1504 are used to align the workpiece placement system to the destination structure. In one embodiment, the workpiece placement system 1502 is transparent to the substrate alignment camera 1505 at the positions of the alignment fiducials 1501 and 1503. The substrate alignment camera takes pictures so that fiducials 1501 and 1503 are in the same pictures, and are used to calculate the position of the workpiece placement system 1502 with respect to the destination structure 1504. In another embodiment, the workpiece placement system 1502 is transparent in near IR wavelengths. The calculated position shift is used to shift the workpiece placement system with respect to the destination structure, as described below in connection with FIG. 17. The workpiece may be a semiconductor die and the destination structure may be a semiconductor substrate.

In another embodiment, the position shift is added to the measured position shift between workpieces and actuator stage as described in connection with FIG. 14 and corrected by the actuator stage. The workpiece may be a semiconductor die.

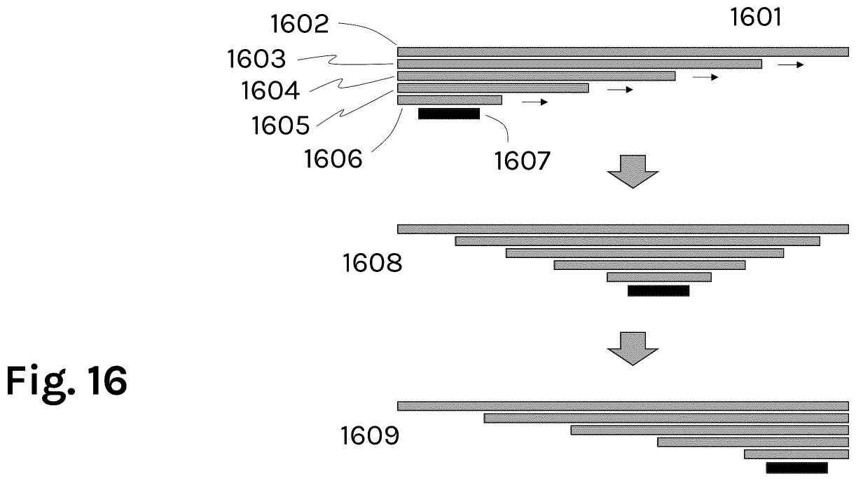

FIG. 16 shows an embodiment in which a plurality of linear stages are stacked on top of each other in a long-range linear motion stage 1601 to achieve a higher speed movement over a distance. The stage 1601 has a stator layer 1602, upon which is attached a stage-1 layer 1603 with a top half configured as a translation layer forming an electro-fluidic transport substrate with the stator layer 1602. The bottom half of the layer 1603 is configured as a stator layer, upon which is attached a stage-2 layer 1604 with the same top and bottom configuration as 1603, with an overall shorter length. Similarly, a stage-3 layer 1605 is attached to layer 1604, and a stage-4 layer 1606 is attached to layer 1605. The bottom half of layer 1606 is configured with a workpiece-handling head, which picks up a payload workpiece 1607. In one embodiment, the substrate 1602 is more than 300 mm long. In one embodiment, all stages move to the right with respect to the previous one at their nominal velocity, moving the workpiece 1607 through the configuration shown in 1608 to the final configuration shown in 1609. The workpiece 1607 is moved from one end of 1601 to the other end with a velocity equal to the sum of the nominal velocities of all stages. The workpiece may be a semiconductor die.

FIG. 17 is a side view of a workpiece placement system 1702 receiving workpieces 1704 from component feeder 1703 and moving via global gantry system 1701 to allow placement of workpieces 1704 on destination structure 1710 in accordance with one embodiment of the invention. Global gantry system 1701 comprises an x/y gantry control 1731 and a z gantry control 1732. Global gantry system 1701 can use a multi stage actuator system, such as described in FIG. 16, and can also use conventional electromagnetic and piezo-electric drivers. In one embodiment, control box 1720 is configured to control global gantry system 1701. In FIG. 17, workpiece placement system 1702 is shown attached to z gantry control 1732. In other embodiments, workpiece placement system 1702 is attached to x/y gantry control 1731 or to an intermediary between global gantry system 1701 and workpiece placements system 1702. The workpiece may be a semiconductor die and the destination structure may be a semiconductor substrate.

Workpiece placement system 1702 receives workpiece 1704 onto empty actuator stage 101 from component feeder 1703. In one embodiment, after placing a workpiece 1704 onto actuator stage 101, component feeder 1703 picks up the next workpiece from workpiece supply tray 1707. In one embodiment, after each placement, workpiece placement system 1702 is shifted to present the next empty actuator stage 101 to component feeder 1703. In other embodiments, component feeder 1703 is shifted to the next position on workpiece placement system 1702. As the workpiece placement system 1702 is shifted, the workpiece position camera 1706 provides picture or video feed by which can be determined the workpiece's position and orientation with respect the workpiece placement system 1702, such as described in FIG. 14. Optionally, the workpiece position camera 1706 is implemented with a system utilizing a set of cameras to monitor positioning of a set of workpieces 1704, wherein the set of workpieces may include many members. The control box 1720 uses the picture or video information to help position the workpieces 1704 properly with respect to the workpiece placement system. The destination structure 1710 is disposed on top of chunk/stage 1712. Substrate alignment camera 1711 aids in the alignment of the workpiece placement system 1702 with the destination structure 1710, as described in connection with FIG. 15. In one embodiment, a plurality of fiducials on workpiece placement system 1702 are checked against the matching fiducials on the destination structure 1710 to produce a position shift map. There may be a plurality of sets of fiducials on the destination structure, to help positioning workpieces in different regions of the destination structure. Additional displacements detected by the substrate alignment camera 1711 are corrected by the global gantry system 1701. When workpieces 1704 are in the correct place over the destination structure 1710, the z gantry control 1732 lowers the workpieces onto the destination structure. The workpiece may be a semiconductor die and the destination structure may be a semiconductor substrate.

In a related embodiment, the workpiece supply tray 1707 is configured to be loaded with workpieces in a manner to correspond with physical positions occupied by the workpieces after they been removably attached to the head of the workpiece placement system 1702. When the workpiece supply tray 1707 is configured in this manner, and the workpiece supply tray 1707 has been populated with workpieces in a plurality of the positions, then, when the head of the workpiece placement system 1702 has been maneuvered above the workpiece supply tray 1707, the head can be used to pick up all these workpieces simultaneously without recourse to the separate component feeder 1703. In this manner, the workpieces can be loaded efficiently into the heads of the workpiece placement system, which can then be used to efficiently place the loaded workpieces onto the destination structure. The workpiece may be a semiconductor die and the destination structure may be a semiconductor substrate.

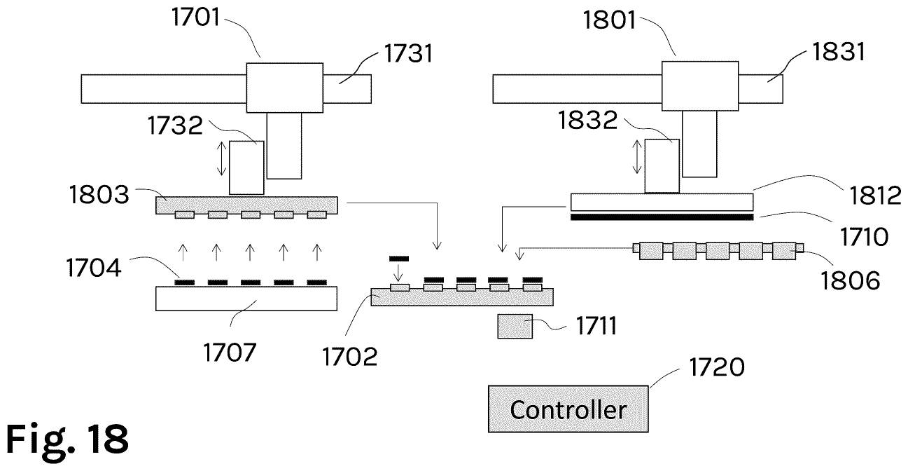

FIG. 18 is a side view of a workpiece placement system 1702 illustrated here (i) receiving workpieces 1704 from the multi-workpiece-transfer-module 1803; (ii) aligning the workpieces 1704 with imaging feedback provided by the multi-imager-module 1806; and (iii) bonding the workpieces 1704 to the destination structure 1710 with the target-bonding-module 1812, all in accordance with an embodiment of the invention. Global gantry system 1701 is used to position the multi-workpiece-transfer-module 1803 to pick up a plurality of workpieces from the workpiece supply tray (i.e., a transport carrier) 1707, which is configured to be loaded with workpieces in a manner to correspond with physical positions occupied by the workpieces after they have been removably attached to the head of the workpiece placement system 1702. The multi-workpiece-transfer-module 1803 is then positioned to place the workpieces 1704 onto the workpiece placement system 1702, before returning to its initial position to be ready for picking up the next set of workpieces from the next transport carrier 1707. Next, the multi-imager-module 1806 is positioned over the workpiece placement system 1702 to capture a set of images or a set of videos by which can be determined the position and orientation of each workpiece with respect to the workpiece placement system 1702. The control box 1720 uses the picture or video information to help position the workpieces 1704 properly with respect to the workpiece placement system 1702. Thereafter, the multi-imager-module 1806 returns from its position over the workpiece placement system 1702. Next, the target-bonding-module 1812 with the destination structure 1710 disposed thereon, moves over to align with the workpiece placement system 1702, with displacement feedback from the substrate alignment camera 1711 and corrected by the global gantry system 1701. When workpieces 1704 are in the correctly aligned over the destination structure 1710, the z-gantry control 1832 lowers the destination structure onto the workpieces. The workpiece may be a semiconductor die and the destination structure may be a semiconductor substrate.

The workpiece-placement system 1702, as shown in FIG. 17 and FIG. 18, may also employ a plurality of conventional drive systems in place of actuator stage 101. Such a conventional drive system may use electromagnetic drives and/or piezo-electric drives to provide high precision position correction in the horizontal plane and/or angular position correction. The achievable density with conventional drive systems is expected to be lower than that of actuator stage 101, yet may nonetheless provide a throughput gain over single-workpiece-placement systems. An example of conventional drive systems providing high-precision position correction in single-die-placement system is disclosed in U.S. Publication No. 2021/0195816, which is hereby incorporated by reference for its disclosure of drive systems. The workpiece may be a semiconductor die.

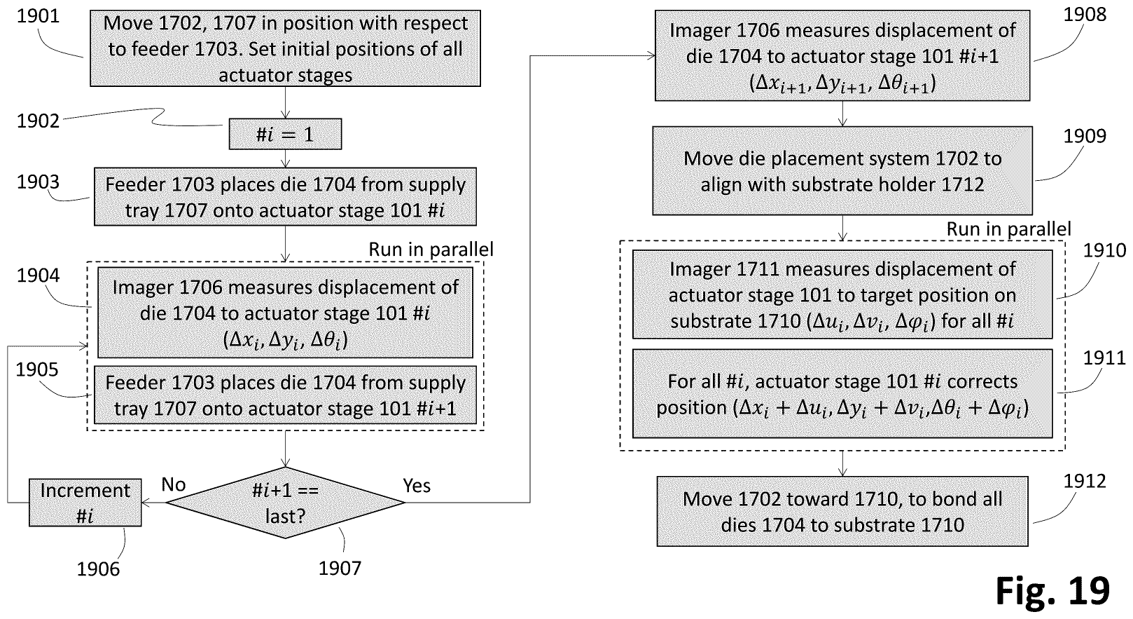

FIG. 19 is a flow-chart of a command sequence that may be executed by control box 1720 to cause performance of the workpiece placement steps illustrated in FIG. 17. At operation 1901, control box 1720 initializes all actuator stage 101 positions before workpiece placement and moves workpiece placement system 1702 and component feeder 1707 into position. At operation 1902, control box 1720 sets index parameter #i to 1. At operation 1903, control box 1720 causes component feeder 1703 to place workpiece 1704 onto first actuator stage 101. At operation 1904, control box 1720 causes imager/camera 1706 to measure displacement of workpiece 1704 placed on stage #i in x, y, and angle as, Δxᵢ, Δyᵢ, Δθᵢ, respectively. At operation 1905, control box 1720 causes component feeder 1703 to place a next workpiece 1704 onto stage #i+1. Operation 1905, the measurement of the displacement of the workpiece 1704 to actuator stage 101 according to FIG. 14 may be executed in parallel with operation 1904, the placement of the next workpiece 1704 onto the next actuator stage 101 by component feeder 1703. At operation 1907, it is checked if a last workpiece has been placed. If no, parameter #i is incremented at operation 1906, and operations 1904 and 1905 are run again. If yes, displacement of the last workpiece 1704 against a last actuator stage is measured at operation 1908. At operation 1909, control box 1720 causes workpiece placement system 1702 to align with substrate holder 1712. At operation 1910, measurement of displacement of actuator stages 101 to target position on the destination structure 1710 may be performed by one or more of imager/camera 1711. At operation 1911, position correction required for each workpiece 1704 may be simultaneously provided by corresponding actuator stage 101. At operation 1912, control box 1720 causes workpiece placement system 1702 to move toward the destination structure 1710, to bond all workpieces 1704 onto the destination structure 1710. The workpiece may be a semiconductor die and the destination structure may be a semiconductor substrate.

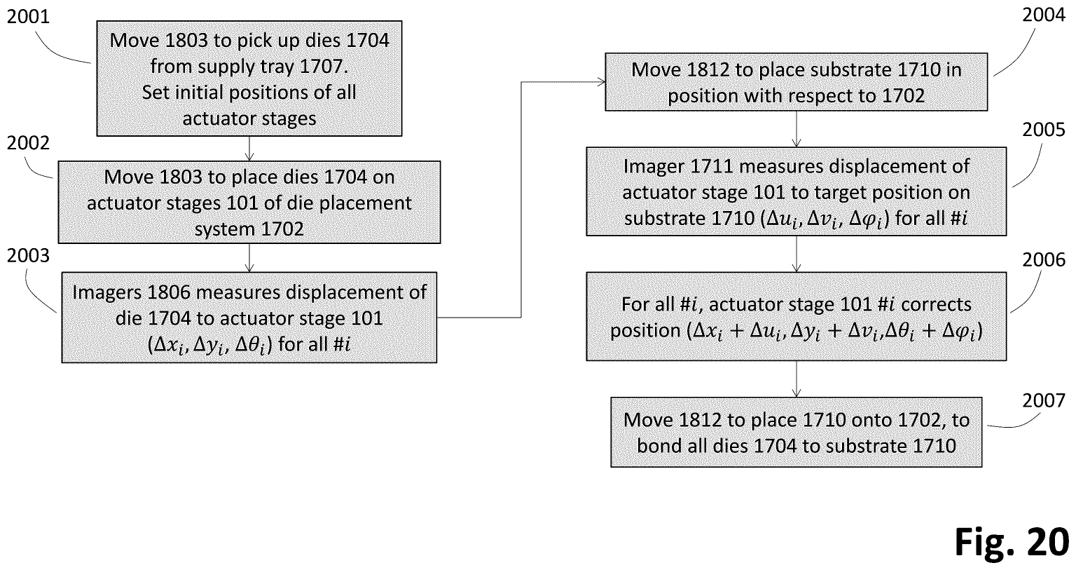

FIG. 20 is a flow-chart of a command sequence that may be executed by control box 1720 to cause performance of the workpiece placement steps illustrated in FIG. 18. At operation 2001, control box 1720 causes multi-workpiece-transfer-module 1803 to pick up a plurality of workpieces from workpiece supply tray 1707; and also to initialize all actuator stage positions. At operation 2002, control box 1720 causes multi-workpiece-transfer-module 1803 to move and place workpieces 1704 onto actuator stages of workpiece placement system 1702. At operation 2003, control box 1720 causes a plurality of imager-modules 1806 to measure displacement of workpieces 1704 from corresponding actuator stages 101 as (Δxᵢ, Δyᵢ, Δθᵢ) for each #i. At operation 2004, control box 1720 causes target-bonding-module 1812 to position the destination structure 1710 in position with respect to workpiece-placement-system 1702. At operation 2005, control box 1720 causes a plurality of imagers/cameras 1711 to measure displacement of actuator stages to target positions on the destination structure 1710 for all stages #i as (Δuᵢ, Δvᵢ, Δφᵢ). At operation 2006, control box 1720 causes each actuator stage 101 #i to correct position in x, y, and angle given by (Δxᵢ+Δuᵢ, Δyᵢ+vᵢ, Δθᵢ+Δφᵢ). At operation 2007, control box 1720 causes bonding-module 1812 to place the destination structure 1710 onto workpiece placement system 1702, to bond all workpieces 1704 onto the destination structure 1710. Operations that do not have mutual dependency, such as operation 2004 versus operation 2003, may be executed in any order or simultaneously. The workpiece may be a semiconductor die and the destination structure may be a semiconductor substrate.

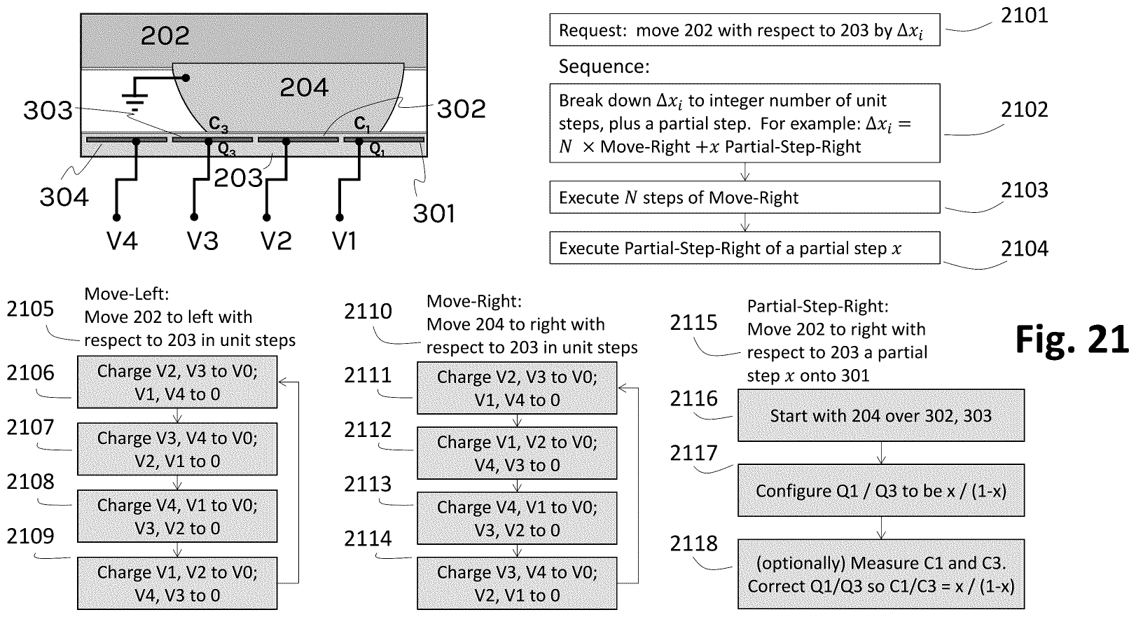

FIG. 21 is an exemplary illustration of command sequences executed by control box 1720 to cause a position change for a linear stage or a rotational stage. Here, four phases are illustrated for each function, although any number of phases may be utilized as would be apparent to one of ordinary skill in the art. To provide position corrections as described in FIG. 19 and FIG. 20, the control box computes the required displacement step (i) for each actuator stage 101, (ii) for x and y displacements, and (iii) for rotation. For example, a movement of Δxᵢ is computed at operation 2101. At operation 2102, the control box computes the required number of unit-steps, and the required partial-step, Δxᵢ=N×Move-Right+x Partial-Step-Right. The control box executes required movement steps by sending corresponding control voltages and charges according to various subroutines. Here, a number of Move-Right steps at operation 2103 and a Partial-Step-Right step at operation 2104 is illustrated. Optionally, the final position may be confirmed by capacitance measurements and/or visual inspection by imagers/cameras 1711, and additional corrections performed if necessary.

At operation 2105, the sequences required to Move Left are illustrated—at operation 2106, V2 and V3 are set to a positive voltage V0, whereas V1 and V4 are set to 0, pulling droplet 204 onto phases 302 and 303. At operation 2107, V3 and V4 are set to V0, whereas V1 and V2 are set to 0, moving the droplet 204 onto phases 303 and 304. At operation 2108, the droplet is pulled onto phases 304 and 301. At operation 2109, the droplet is pulled onto phases 301 and 302. Cycling through operations 2106 through 2109 moves the droplet progressively to the left in integer steps.

At operation 2110, the sequences required to Move Right are illustrated. Cycling through operations 2111 through 2114 moves the droplet progressively to the right in integer steps.

At operation 2115, the sequences required to perform a partial step to the right is illustrate for when the droplet 204 starts on top of phases 302 and 303 as in operation 2116. At operation 2117, control box 1720 configures the charges in phases 301 and 303 to take on the ratio Q1/Q3=x/(1−x), where x is the required partial step size between 0 and 1. This will move droplet 204 to increase C1 and reduce C3 until C1/C3=x/(1−x). Optionally, at operation 2118, the final position is verified by measured C1/C3, and/or visually measured position, and error signal is used to correct Q1/Q3 until final desired position is achieved.

Various embodiments of the present invention may be characterized by the potential claims listed in the paragraphs following this paragraph (and before the actual claims provided at the end of this application). These potential claims form a part of the written description of this application. Accordingly, subject matter of the following potential claims may be presented as actual claims in later proceedings involving this application or any application claiming priority based on this application. Inclusion of such potential claims should not be construed to mean that the actual claims do not cover the subject matter of the potential claims. Thus, a decision to not present these potential claims in later proceedings should not be construed as a donation of the subject matter to the public.

Without limitation, potential subject matter that may be claimed (prefaced with the letter “P” so as to avoid confusion with the actual claims presented below) includes:

P1. An actuator stage, for precision positioning of a component, the actuator stage comprising:
a base layer having a surface defining a z-axis normal to the surface;
a set of electro-fluidic transport substrates, disposed on the base layer, each of the substrates having:
   a set of arrays of electrodes at a spatial frequency;
   a dielectric layer, disposed over the set of arrays of electrodes and having a hydrophobic surface;
   a fluidic layer disposed over the hydrophobic surface and including a first non-conductive liquid and a second conductive liquid, wherein the first and second liquids are immiscible; and
   a carrier layer having defined hydrophilic and hydrophobic regions in selected contact with the second conductive liquid and the first non-conductive liquid, respectively, configured in a manner so that appropriate powering of the electrodes effectuates motion of the carrier layer;
   wherein any electro-fluidic transport substrate after a first one of the set is disposed over another one of the set; and
a control port, coupled to the set of arrays of electrodes in each of the electro-fluidic transport substrates, configured to cause selective delivery, to a set of electrodes in the set of arrays of electrodes, of a current pulse having a profile controlled over time to regulate an amount of charge delivered to each electrode in the set of arrays of electrodes, so as to effectuate translation of the carrier layer in the electro-fluidic transport substrate in desired fractions of the spatial frequency of the set of arrays of electrodes.

P2. The actuator stage, according to potential claim P1, having first and second subsets of electro-fluidic transport substrates, wherein:
a. each array of the set of arrays of electrodes in each transport substrate of the first subset is a linear array, and the set of arrays of electrodes are configured by the control port to cause translation of its corresponding carrier layer in x- and y-directions of an orthogonal axis system that defines a plane normal to the z-axis; and
b. each array of the set of arrays of electrodes in each transport substrate of the second subset is a circular array configured by the control port to cause rotation about the z-axis of its corresponding carrier layer.

P3. The actuator stage according to potential claim P2, wherein the set of electro-fluidic transport substrates has a last member spaced farthest, of all members of the set, from the surface of the base layer, further comprising a handling head, mounted over the last member of the set of electro-fluidic transport substrates, configured to removably hold onto a workpiece to be placed onto a destination structure.

P4. A set of actuator stages, each actuator stage configured according to the actuator stage of potential claim P3, wherein the actuator stages of the set are configured to process a plurality of workpieces simultaneously.

P5. The set of actuator stages according to potential claim P4, wherein the workpiece is a semiconductor die and the destination structure is a semiconductor substrate.

P6. An electro-fluidic transport system configured to handle a plurality of workpieces, the transport system having a plurality of translatable actuator stages arranged in a grid, each actuator stage configured to support and to translate a selected one of the workpieces, wherein each actuator stage comprises:
a base layer having a surface defining a z-axis normal to the surface;
a set of electro-fluidic transport substrates, such electro-fluidic transport substrates being stacked if a plurality thereof are present, the set thereof being disposed on the base layer, each of the substrates having:
   a set of arrays of electrodes at a spatial frequency;
   a dielectric layer, disposed over the set of arrays of electrodes and having a hydrophobic surface;
   a fluidic layer disposed over the hydrophobic surface and including a first non-conductive liquid and a second conductive liquid, wherein the first and second liquids are immiscible; and
   a carrier layer having defined hydrophilic and hydrophobic regions in selected contact with the second conductive liquid and the first non-conductive liquid, respectively, configured in a manner so that appropriate powering of the electrodes effectuates motion of the carrier layer; and
a control port, coupled to the set of arrays of electrodes in each of the electro-fluidic transport substrates, configured to cause selective delivery, to a set of electrodes in the set of arrays of electrodes, of a current pulse received thereat having a profile controlled over time to regulate an amount of charge delivered to each electrode in the set of arrays of electrodes, so as to effectuate translation of the carrier layer in the electro-fluidic transport substrate in desired fractions of the spatial frequency of the set of arrays of electrodes.

P7. The electro-fluidic transport system of potential claim P6, further comprising:
a controller coupled to the control port of each actuator stage to provide current pulses configured to effectuate desired translation of each of the actuator stages.

P8. The electro-fluidic transport system according to any one of potential claims P6-P7, wherein the workpiece is a semiconductor die.

P9. A transport system having a plurality of translatable actuator stages arranged over a region and mounted in a rigid framework, each actuator stage configured to receive a workpiece and rendered independently translatable by an actuator type selected from the group consisting of an electro-fluidic actuator, an electromagnetic actuator, and a piezo-electric actuator.

P10. The transport system of potential claim P9, wherein each actuator stage uses an electro-fluidic actuator having a stack of layers configured to achieve translation in accordance with a current profile delivered thereto.

P11. The transport system according to any one of potential claims P9 and P10, wherein the plurality of translatable actuator stages comprises at least four members.

P12. The transport system according to any one of potential claims P9-P11, wherein the workpiece is a semiconductor die.

P13. A method of causing precise positioning of a set of at least four workpieces, the method comprising:
providing an electro-fluidic transport system having a number of electro-fluidic actuator stages at least as large as a number of the members in the set of workpieces;
placing each of the workpieces on a corresponding one of the electro-fluidic actuator stages; and
causing, by a set of controllers coupled to electro-fluidic transport substrates of the electro-fluidic actuator stages, generation of a current pulse shaped to cause translation of each workpiece of the set of workpieces to a desired position, so as to cause the set of workpieces to be precisely positioned.

P14. The method of potential claim P13, wherein the desired position of each of the workpieces is determined by analyzing images acquired by a set of workpiece position cameras configured to provide data identifying a position each of the workpieces on its corresponding electro-fluidic actuator stage.

P15. The method according to any one of potential claims P13-P14, further comprising:
after the set of workpieces has been precisely positioned, bringing a destination structure into contact with them; and
causing the set of workpieces to be bonded to the destination structure.

P16. The method according to any one of potential claims P13-P15, wherein the set of at least four workpieces is a set of at least four semiconductor dies, and the destination structure is a semiconductor substrate.

P17. An apparatus for precise positioning of a plurality workpieces, the apparatus comprising:
the electro-fluidic transport system according to any one of potential claims P6-P8;
a set of workpiece position cameras configured to provide data identifying a position each of the workpieces on its corresponding electro-fluidic actuator stage; and
a workpiece supply tray.

P18. The apparatus of potential claim P17, further comprising a set of substrate alignment cameras configured to determine the position of the carrier layer relative to a destination structure.

The embodiments of the invention described above are intended to be merely exemplary; numerous variations and modifications will be apparent to those skilled in the art. All such variations and modifications are intended to be within the scope of the present invention as defined in any appended claims.

What is claimed is:

1. An actuator stage, for precision positioning of a component, the actuator stage comprising:
a base layer having a surface defining a z-axis normal to the surface;
a set of electro-fluidic transport substrates, disposed on the base layer, each of the substrates having:
a set of arrays of electrodes at a spatial frequency;
a dielectric layer, disposed over the set of arrays of electrodes and having a hydrophobic surface;
a fluidic layer disposed over the hydrophobic surface and including a first non-conductive liquid and a second conductive liquid, wherein the first and second liquids are immiscible; and
a carrier layer having defined hydrophilic and hydrophobic regions in selected contact with the second conductive liquid and the first non-conductive liquid, respectively, configured in a manner so that appropriate powering of the electrodes effectuates motion of the carrier layer;
wherein any electro-fluidic transport substrate after a first one of the set is disposed over another one of the set; and
a control port, coupled to the set of arrays of electrodes in each of the electro-fluidic transport substrates, configured to cause selective delivery, to a set of electrodes in the set of arrays of electrodes, of a current pulse having a profile controlled over time to regulate an amount of charge delivered to each electrode in the set of arrays of electrodes, so as to effectuate translation of the carrier layer in the electro-fluidic transport substrate in desired fractions of the spatial frequency of the set of arrays of electrodes.

2. The actuator stage, according to claim 1, having first and second subsets of electro-fluidic transport substrates, wherein:
a. each array of the set of arrays of electrodes in each transport substrate of the first subset is a linear array, and the set of arrays of electrodes are configured by the control port to cause translation of its corresponding carrier layer in x- and y-directions of an orthogonal axis system that defines a plane normal to the z-axis; and
b. each array of the set of arrays of electrodes in each transport substrate of the second subset is a circular array configured by the control port to cause rotation about the z-axis of its corresponding carrier layer.

3. The actuator stage of claim 2, wherein the set of electro-fluidic transport substrates has a last member spaced farthest, of all members of the set, from the surface of the base layer, further comprising a handling head, mounted over the last member of the set of electro-fluidic transport substrates, configured to removably hold onto a workpiece to be placed onto a destination structure.

4. A set of actuator stages, each actuator stage configured according to the actuator stage of claim 3, wherein the actuator stages of the set are configured to process a plurality of workpieces simultaneously.

5. The set of actuator stages of claim 4, wherein the workpiece is a semiconductor die and the destination structure is a semiconductor substrate.

6. An electro-fluidic transport system configured to handle a plurality of workpieces, the transport system having a plurality of translatable actuator stages arranged in a grid, each actuator stage configured to support and to translate a selected one of the workpieces, wherein each actuator stage comprises:
a base layer having a surface defining a z-axis normal to the surface;
a set of electro-fluidic transport substrates, such electro-fluidic transport substrates being stacked if a plurality thereof are present, the set thereof being disposed on the base layer, each of the substrates having:
a set of arrays of electrodes at a spatial frequency;
a dielectric layer, disposed over the set of arrays of electrodes and having a hydrophobic surface;
a fluidic layer disposed over the hydrophobic surface and including a first non-conductive liquid and a second conductive liquid, wherein the first and second liquids are immiscible; and
a carrier layer having defined hydrophilic and hydrophobic regions in selected contact with the second conductive liquid and the first non-conductive liquid, respectively, configured in a manner so that appropriate powering of the electrodes effectuates motion of the carrier layer; and
a control port, coupled to the set of arrays of electrodes in each of the electro-fluidic transport substrates, configured to cause selective delivery, to a set of electrodes in the set of arrays of electrodes, of a current pulse received thereat having a profile controlled over time to regulate an amount of charge delivered to each electrode in the set of arrays of electrodes, so as to effectuate translation of the carrier layer in the electro-fluidic transport substrate in desired fractions of the spatial frequency of the set of arrays of electrodes.

7. The electro-fluidic transport system of claim 6, further comprising:
a controller coupled to the control port of each actuator stage to provide current pulses configured to effectuate desired translation of each of the actuator stages.

8. The electro-fluidic transport system of claim 6, wherein the workpiece is a semiconductor die.

9. A transport system having a plurality of translatable actuator stages arranged over a region and mounted in a rigid framework, each actuator stage configured to receive a workpiece and rendered independently translatable by an actuator type selected from the group consisting of an electro-fluidic actuator, an electromagnetic actuator, and a piezo-electric actuator.

10. The transport system of claim 9, wherein each actuator stage uses an electro-fluidic actuator having a stack of layers configured to achieve translation in accordance with a current profile delivered thereto.

11. The transport system of claim 9, wherein the plurality of translatable actuator stages comprises at least four members.

12. The transport system of claim 9, wherein the workpiece is a semiconductor die.

13. A method of causing precise positioning of a set of at least four workpieces, the method comprising:
providing an electro-fluidic transport system having a number of electro-fluidic actuator stages at least as large as a number of the members in the set of workpieces;
placing each of the workpieces on a corresponding one of the electro-fluidic actuator stages; and
causing, by a set of controllers coupled to electro-fluidic transport substrates of the electro-fluidic actuator stages, generation of a current pulse shaped to cause translation of each workpiece of the set of workpieces to a desired position, so as to cause the set of workpieces to be precisely positioned.

14. The method of claim 13, wherein the desired position of each of the workpieces is determined by analyzing images acquired by a set of workpiece position cameras configured to provide data identifying a position each of the workpieces on its corresponding electro-fluidic actuator stage.

15. The method of claim 13, further comprising:
after the set of workpieces has been precisely positioned, bringing a destination structure into contact with them; and
causing the set of workpieces to be bonded to the destination structure.

16. The method of claim 13, wherein the set of at least four workpieces is a set of at least four semiconductor dies, and the destination structure is a semiconductor substrate.

17. An apparatus for precise positioning of a plurality workpieces, the apparatus comprising:
the electro-fluidic transport system of claim 6;
a set of workpiece position cameras configured to provide data identifying a position each of the workpieces on its corresponding electro-fluidic actuator stage; and
a workpiece supply tray.

18. The apparatus of claim 17, further comprising a set of substrate alignment cameras configured to determine the position of the carrier layer relative to a destination structure.
